(19) United States
(12) Patent Application Publication
(10) Pub. No.: US 2012/0032135 A1
(43) Pub. Date: Feb. 9, 2012

(54) Phase-Change Memory Units and Phase-Change Memory Devices Using the Same

(76) Inventors: Bong-Jin KUH, Gyeonggi-do (KR); Yong-Ho HA, Gyeonggi-do (KR); Doo-Hwan PARK, Gyeonggi-do (KR); Han-Bong KO, Gyeonggi-do (KR); Sang-Wook LIM, Gyeonggi-do (KR); Hee-Ju SHIN, Gyeonggi-do (KR)

(21) Appl. No.: 13/276,084

(22) Filed: Oct. 18, 2011

Related U.S. Application Data
(63) Continuation of application No. 11/860,829, filed on Sep. 25, 2007.

(30) Foreign Application Priority Data
Sep. 27, 2006 (KR) 2006-94225

(51) Int. Cl. H01L 47/00

(52) U.S. Cl. 257/4; 257/E47.001

(57) ABSTRACT

A phase-change material layer is formed on the lower electrode using a chalcogenide compound doped with carbon, or carbon and nitrogen. A phase-change material layer is obtained by doping a stabilizing metal into the preliminary phase-change material layer. An upper electrode is formed on the phase-change material layer. Since the phase-change material layer may have improved electrical characteristics, stability of phase transition and thermal stability, the phase-change memory unit may have reduced set resistance, enhanced durability, improved reliability, increased sensing margin, reduced driving current, etc.

### CROSS-REFERENCE TO RELATED APPLICATIONS

This application is a continuation of U.S. application Ser. No. 11/860,829 filed on Sep. 25, 2007 which claims priority under 35 USC §119 to Korean Patent Application No. 10-2006-0094225 filed on Sep. 27, 2006, the contents of which are incorporated herein by reference in their entireties.

### FIELD OF THE INVENTION

Example embodiments of the present invention relate to a method of manufacturing a phase-change memory unit and a method of manufacturing a phase-change memory device having the phase-change memory unit. More particularly, example embodiments of the present invention relates a method of manufacturing a phase-change memory unit having improved electrical characteristics and durability by doping a stabilizing metal into a phase-change material layer including a chalcogenide compound doped with carbon and/or nitrogen, and a method manufacturing a phase-change memory device having the phase-change memory unit.

### BACKGROUND OF THE INVENTION

Semiconductor memory devices are generally divided into volatile semiconductor memory devices such as dynamic random access memory (DRAM) devices or static random access memory (SRAM) devices, and non-volatile semiconductor memory devices such as flash memory devices or electrically erasable programmable read only memory (EEPROM) devices. The volatile semiconductor memory device loses data stored therein when power is off. However, the non-volatile semiconductor memory device keeps stored data even if power is out.

Among the non-volatile semiconductor memory devices, the flash memory device has been widely employed in various electronic apparatuses such as a digital camera, a cellular phone, an MP3 player, etc. Since a programming process and a reading process of the flash memory device take a relatively long time, technologies to manufacture a novel semiconductor memory device, for example, a magnetic random access memory (MRAM) device, a ferroelectric random access memory (FRAM) device or a phase-change random access memory (PRAM) device, have been constantly developed.

The phase-change memory device stores information using a resistance difference between an amorphous phase and a crystalline phase of a phase-change material layer composed of a chalcogenide compound, e.g., germanium-antimony-tellurium (GST). Particularly, the PRAM device may store data as states of “0” and “1” using a reversible phase transition of the phase-change material layer. The amorphous phase of the phase-change material layer has a large resistance, whereas the crystalline phase of the phase-change material layer has a relatively small resistance. In the PRAM device, a transistor formed on a substrate may provide the phase-change material layer with a reset current (Iᵣₑₛₑₜ) for changing the phase of the phase-change material layer from the crystalline state into the amorphous state. The transistor may also supply the phase-change material layer with a set current (Iₛₑₜ) for changing the phase of the phase-change material layer from the amorphous state into the crystalline state. The conventional PRAM device is disclosed in U.S. Pat. No. 5,596,522, U.S. Pat. No. 5,825,046, U.S. Pat. No. 6,919,578, Korean Laid-Open Patent Publication No. 2004-100499 and Korean Laid-Open Patent Publication No. 2003-81900.

FIGS. 1A to 1C are cross-sectional views showing a method of manufacturing the conventional phase-change memory device.

Referring to FIG. 1A, a contact region 5 is formed at a portion of a semiconductor substrate 1 by implanting impurities. The contact region 5 is formed by an ion implanting process.

A first insulating interlayer 10 covering the contact region 5 is formed on the semiconductor substrate 1. The first insulating interlayer 10 is formed using silicon oxide by a chemical vapor deposition (CVD) process.

The first insulating interlayer 10 is etched by a photolithography process so that a contact hole (not shown) is formed through the first insulating interlayer 10. The contact hole exposes the contact region 5 of the semiconductor substrate 1.

A first conductive layer (not shown) is formed on the contact region 5 and the first insulating interlayer 10 to fill the contact hole. The first conductive layer is formed using metal or doped polysilicon.

The first conductive layer is removed until the first insulating interlayer 10 is exposed so that a pad 15 filling the contact hole is formed on the contact region 5. The pad 15 is formed by a chemical mechanical polishing (CMP) process.

A second conductive layer (not shown) is formed on the pad 15 and the first insulating interlayer 10, and then the second conductive layer is patterned by a photolithography process to form a lower electrode 20 on the pad 15 and the first insulating interlayer 10. The lower electrode 20 is electrically connected to the contact region 5 through the pad 15.

Referring to FIG. 1B, a preliminary second insulating interlayer (not shown) is formed on the first insulating interlayer 10 to cover the lower electrode 20. The preliminary second insulating interlayer is formed using oxide by a CVD process.

The preliminary second insulating interlayer is removed until the lower electrode 20 is exposed such that a second insulating interlayer 25 is formed on the first insulating interlayer 10.

A first oxide layer 30, a nitride layer 35 and a second oxide layer 40 are sequentially formed on the second insulating interlayer 25. The first and the second oxide layers 30 and 40 are formed using silicon oxide, and the nitride layer 35 is formed using silicon nitride.

The second oxide layer 40, the nitride layer 35 and the first oxide layer 30 are etched by a photolithography process, thereby forming an opening (not shown) through the first oxide layer 30, the nitride layer 35 and the second oxide layer 40. The lower electrode 20 is exposed through the opening.

A phase-change material layer 45 is formed on the lower electrode 20 and the second oxide layer 40 by depositing a chalcogenide compound of GST on the lower electrode 20 and the second oxide layer 40.

Referring to FIG. 1C, the phase-change material layer 45 is polished until the second oxide layer 40 is exposed so that a phase-change material layer pattern 50 filling the opening is formed on the lower electrode 20.

After a third conductive layer (not shown) is formed on the phase-change material layer pattern 50 and the second oxide layer 40, the third conductive layer is patterned to form an upper electrode 55 on the phase-change material layer pattern 50 and the second oxide layer 40.

In the above-mentioned method of manufacturing the conventional PRAM device, the phase stability and the resistance stability of the phase-change material layer may be considerably deteriorated because the phase-change material layer of GST is directly formed on the lower electrode while filling the opening. Thus, the conventional PRAM device may have poor electrical characteristics and reliability.

Considering the above-mentioned problems, a phase-change material layer has been formed using a chalcogenide compound doped with nitrogen in order to improve electrical characteristics of a phase-change memory device including the phase-change material layer. For example, Korean Laid-Open Patent Publication 2004-76225 discloses a phase-change memory device including a phase-change material layer composed of a GST compound doped with nitrogen. However, in the above-mentioned phase-change memory device having the phase-change material layer pattern of the GST compound doped with nitrogen, the phase-change memory device may have considerably large initial writing current although the set resistance of the phase-change memory device may be decreased. To improve an integration degree of the phase-change memory device, the driving current of the phase-change memory device needs to be reduced. However, the set resistance of the phase-change memory device may be greatly increased in accordance with the reduction of the driving current thereof when the phase-change material layer of the phase-change memory device includes the GST compound doped with nitrogen only. Further, the phase-change memory device of the GST compound doped with nitrogen may not ensure good adhesion strength relative to the lower electrode and the upper electrode. Thus, the lower electrode and/or the upper electrode may be separated from the phase-change material layer, and also the interface resistance between the lower electrode and the phase-change material layer or the upper electrode and the phase-change material layer may be undesirably reduced.

### SUMMARY OF THE INVENTION

Example embodiments of the present invention provide a method of manufacturing a phase-change memory unit including a phase-change material layer containing a chalcogenide compound doped with carbon and a stabilizing metal, or carbon, nitrogen and a stabilizing metal.

Example embodiment of the present invention provide a method of manufacturing a phase-change memory device including a phase-change material layer containing a chalcogenide compound doped with carbon and a stabilizing metal, or carbon, nitrogen and a stabilizing metal.

According to one aspect of the present invention, there is provided a method of manufacturing a phase-change memory unit. In the method of manufacturing the phase-change memory unit, a contact region is formed on a substrate, and then a lower electrode is formed to be electrically connected to the contact region. A preliminary phase-change material layer is formed on the lower electrode using a chalcogenide compound doped with carbon or a chalcogenide compound doped with carbon and nitrogen. After a phase-change material layer is formed on the lower electrode by doping a stabilizing metal into the preliminary phase-change material layer, an upper electrode is formed on the phase-change material layer.

In some example embodiments, an insulation structure may be formed on the substrate before forming the lower electrode. The insulation structure may include at least one pad electrically connected to the contact region. The lower electrode may be buried in the insulation structure.

In some example embodiments, the stabilizing metal may include titanium (Ti), nickel (Ni), zirconium (Zr), molybdenum (Mo), ruthenium (Ru), palladium (Pd), hafnium (Hf), tantalum (Ta), iridium (Ir) or platinum (Pt). These may be used alone or in a mixture thereof.

In some example embodiments, the preliminary phase-change material layer may be formed by a sputtering process or a chemical vapor deposition (CVD) process.

In some example embodiments, the preliminary phase-change material layer may be formed using one target including the chalcogenide compound doped with carbon. Alternatively, the preliminary phase-change material layer may be formed using one target including the chalcogenide compound doped with carbon under an atmosphere containing nitrogen.

In some example embodiments, the preliminary phase-change material layer may be formed by simultaneously using a first target including carbon and a second target including a chalcogenide compound. Alternatively, the preliminary phase-change material layer may be formed by simultaneously using a first target including carbon and a second target including a chalcogenide compound under an atmosphere containing nitrogen.

In some example embodiments, the preliminary phase-change material layer may be formed by simultaneously using a first target including carbon, a second target including germanium-tellurium and a third target including antimony-tellurium. Alternatively, the preliminary phase-change material layer may be formed by simultaneously using a first target including carbon, a second target including germanium-tellurium and a third target including antimony-tellurium under an atmosphere containing nitrogen.

In some example embodiments, the phase-change material layer may be formed using an additional target including the stabilizing metal in the sputtering process for forming the preliminary phase-change material layer.

In some example embodiments, the phase-change material layer may be formed by an additional sputtering process that uses a target including the stabilizing metal.

In some example embodiments, the preliminary phase-change material layer may be formed using a first source gas including germanium, a second source gas including antimony, a third source gas including tellurium and a reaction gas including carbon. Alternatively, the preliminary phase-change material layer may be formed using a first source gas including germanium, a second source gas including antimony, a third source gas including tellurium, a first reaction gas including carbon, and a second reaction gas including nitrogen.

In some example embodiments, the preliminary phase-change material layer may be formed using a source gas including germanium, antimony and tellurium and a reaction gas including carbon. Alternatively, the preliminary phase-change material layer may be formed using a source gas including germanium, antimony and tellurium, and a reaction gas including carbon and nitrogen.

In some example embodiments, the phase-change material layer may be formed using an additional source gas including the stabilizing metal in the CVD process for forming the preliminary phase-change material layer.

In some example embodiments, the phase-change material layer may be formed by an additional CVD process that uses a source gas including the stabilizing metal.

In some example embodiments, forming the preliminary phase-change material layer and forming the phase-change material layer may be performed in-situ under a vacuum atmosphere or an inactive gas atmosphere.

In a formation of the upper electrode according to some example embodiments, a first upper electrode film may be formed on the phase-change material layer, and then a second upper electrode film may be formed on the first upper electrode film. The first upper electrode film may be formed using titanium, nickel, zirconium, molybdenum, ruthenium, palladium, hafnium, iridium or platinum. These may be used alone or in a mixture thereof. The second upper electrode film may be formed using titanium nitride, nickel nitride, zirconium nitride, molybdenum nitride, ruthenium nitride, palladium nitride, hafnium nitride, tantalum nitride, iridium nitride, platinum nitride, tungsten nitride, aluminum nitride, niobium nitride, titanium silicon nitride, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride or tantalum aluminum nitride. These may be used alone or in a mixture thereof.

In some example embodiments, the phase-change material layer may include a chalcogenide compound doped with carbon and the stabilizing metal in accordance with the following chemical formula (1):

C_{A}M_{B}[Ge_{X}Sb_{Y}Te_{(100-X-Y)}]_{(100-A-B)} (1)

In the above chemical formula (1), C indicates carbon, N represents the stabilizing metal, 0.2≦A≦30.0, 0.1≦B≦15.0, 0.1≦X≦30.0 and 0.1≦Y≦90.0.

In some example embodiments, the phase-change material layer may include a chalcogenide compound doped with carbon and the stabilizing metal in accordance with the following chemical formula (2):

C_{A}M_{B}[Ge_{X}Z_{(100-X)}Sb_{Y}Te_{(100-X-Y)}]_{(100-A-B)} (2)

In the above chemical formula (2), Z includes silicon (Si) or tin (Sn), 0.2≦A≦30.0, 0.1≦B≦15.0, 0.1≦X≦80.0, and 0.1≦Y≦90.0.

In some example embodiments, the phase-change material layer may include a chalcogenide compound doped with carbon and the stabilizing metal in accordance with the following chemical formula (3):

C_{A}M_{B}[Ge_{X}Sb_{Y}T_{(100-Y)}Te_{(100-X-Y)}]_{(100-A-B)} (3)

In the above chemical formula (3), T includes arsenic (As) or bismuth (Bi), 0.2≦A≦30.0, 0.1≦B≦15.0, 0.1≦X≦90.0, and 0.1≦Y≦80.0.

In some example embodiments, the phase-change material layer may include a chalcogenide compound doped with carbon and the stabilizing metal in accordance with the following chemical formula (4):

C_{A}M_{B}[Ge_{X}Sb_{Y}Q_{(100-X-Y)}]_{(100-A-B)} (4)

In the above chemical formula (4), Q includes antimony and selenium, 0.2≦A≦30.0, 0.1≦B≦15.0, 0.1≦X≦30.0, 0.1≦Y≦90.0, Q indicates Sb_{D}Te_{(100-D)}, and 0.1≦D≦80.0.

In some example embodiments, the phase-change material layer may include a chalcogenide compound doped with carbon, nitrogen and the stabilizing metal in accordance with the following chemical formula (5):

C_{A}M_{B}N_{C}[Ge_{X}Sb_{Y}Te_{(100-X-Y)}]_{(100-A-B-C)} (5)

In the above chemical formula (5), C means carbon, M denotes the stabilizing metal, N indicates nitrogen, 0.2≦A≦30.0, 0.1≦B≦15.0, 0.1X≦10.0, 0.1≦Y≦30.0 and 0.1≦Yv90.0.

In some example embodiments, the phase-change material layer may include a chalcogenide compound doped with carbon, nitrogen and the stabilizing metal in accordance with the following chemical formula (6):

C_{A}M_{B}N_{C}[Ge_{X}Z_{(100-X)}Sb_{Y}Te_{(100-X-Y)}]_{(100-A-B-C)} (6)

In the above chemical formula (6), Z includes silicon or tin, 0.2≦A≦30.0, 0.1≦B≦15.0, 0.1≦C≦10.0, 0.1≦X≦80.0 and 0.1≦Y≦90.0.

In some example embodiments, the phase-change material layer may include a chalcogenide compound doped with carbon, nitrogen and the stabilizing metal in accordance with the following chemical formula (7):

C_{A}M_{B}N_{C}[Ge_{X}Sb_{Y}T_{(100-Y)}Te_{(100-X-Y)}]_{(100-A-B-C)} (7)

In the above chemical formula (7), T includes arsenic or bismuth, 0.2≦A≦30.0, 0.1≦B≦15.0, 0.1≦C≦10.0, 0.1≦X≦90.0 and 0.1≦Y≦80.0.

In some example embodiments, the phase-change material layer may include a chalcogenide compound doped with carbon, nitrogen and the stabilizing metal in accordance with the following chemical formula (8):

C_{A}M_{B}N_{C}[Ge_{X}Sb_{Y}Q_{(100-X-Y)}]_{(100-A-B)} (8)

In the above chemical formula (8), Q includes antimony and selenium, 0.2≦A≦30.0, 0.1≦B15.0, 0.1≦C≦10.0, 0.1≦X≦30.0 and 0.1≦Yv90.0. Further, Q indicates Sb_{D}Te_{100-D)}, and 0.1≦D≦80.0.

According to another aspect of the present invention, there is provided a method of manufacturing a phase-change memory unit. In the method of manufacturing the phase-change memory unit, a contact region is formed on a substrate. A lower electrode is formed on the substrate. The lower electrode is electrically connected to the contact region. A preliminary phase-change material layer is formed on the lower electrode using a chalcogenide compound doped with carbon or a chalcogenide compound doped with carbon and nitrogen. An upper electrode is formed on the preliminary phase-change material layer. The preliminary phase-change material layer is changed into a phase-change material layer by doping a stabilizing metal into the preliminary phase-change material layer.

In a formation of the upper electrode according to some example embodiments, a first upper electrode film including the stabilizing metal may be formed on the preliminary phase-change material layer. A second upper electrode film including a metal nitride may be formed on the first upper electrode film.

In a formation of the phase-change material layer according to some example embodiments, a stabilizing process may be performed on the preliminary phase-change material layer and the upper electrode layer. For example, the stabilizing process may be carried out at a temperature of about 300 to about 800° C. for about 10 minutes to about 4 hours under an inactive gas atmosphere. The stabilizing metal may be diffused from the first upper electrode film into the preliminary phase-change material layer in the stabilizing process.

According to still another aspect of the present invention, there is provided a method of manufacturing a phase-change memory device. In the method of manufacturing the phase-change memory device, a contact region is formed on a substrate. A switching element is formed on the substrate. The switching element is electrically connected to the contact region. An insulating interlayer is formed on the substrate to cover the switching element. A lower electrode is formed on the insulating interlayer. The lower electrode is electrically connected to the contact region. A preliminary phase-change material layer is formed on the lower electrode using a chalcogenide compound doped with carbon or a chalcogenide compound doped with carbon and nitrogen. A phase-change material layer is formed on the lower electrode by doping a stabilizing member into the preliminary phase-change material layer. An upper electrode is formed on the phase-change material layer. In a formation of the upper electrode, a first upper electrode film is formed on the phase-change material layer, and then a second upper electrode film is formed on the first upper electrode film.

According to still another aspect of the present invention, there is provided a method of manufacturing a phase-change memory device. In the method of manufacturing the phase-change memory device, a contact region is formed on a substrate, and a switching element is formed on the substrate. The switching element is electrically connected to the contact region. An insulating interlayer is formed on the substrate to cover the switching element. A lower electrode is formed on the insulating interlayer. The lower electrode is electrically connected to the contact region. A preliminary phase-change material layer is formed on the lower electrode using a chalcogenide compound doped with carbon or a chalcogenide compound doped with carbon and nitrogen. An upper electrode is formed on the preliminary phase-change material layer. The preliminary phase-change material layer is changed into a phase-change material layer by doping a stabilizing member into the preliminary phase-change material layer.

According to example embodiments of the present invention, a phase-change material layer may be obtained by doping a stabilizing metal into a chalcogenide compound doped with carbon, or carbon and nitrogen, so that the phase-change material layer may have improved electrical characteristics, an enhanced stability of a phase transition, improved thermal characteristics, etc. When a phase-change memory unit or a phase-change memory device includes the phase-change material layer of a chalcogenide compound doped with carbon and the stabilizing metal, or carbon, nitrogen and the stabilizing metal, the phase-change memory unit or the phase-change memory device may have a considerably reduced set resistance, enhanced durability, improved reliability, etc. Further, the phase-change memory unit or the phase-change memory device may have enlarged sensing margin while efficiently reducing driving current thereof.

### BRIEF DESCRIPTION OF THE DRAWINGS

The above and other features and advantages of the present invention will become readily apparent by reference to the following detailed description when considered in conjunction with the accompanying drawings wherein:

FIGS. 1A to 1C are cross-sectional views illustrating a method of manufacturing a conventional phase-change memory unit;

FIGS. 2A to 2D are cross sectional views illustrating a method of manufacturing a phase-change memory unit in accordance with example embodiments of the present invention;

FIGS. 3A to 3C are cross sectional views illustrating a method of manufacturing a phase-change memory unit in accordance with example embodiments of the present invention;

FIGS. 4A to 4C are cross sectional views illustrating a method of manufacturing a phase-change memory unit in accordance with example embodiments of the present invention;

FIG. 5 is a graph illustrating a driving current of a conventional phase-change memory device including a phase-change material layer of a GST compound without a stabilizing metal;

FIG. 6 is a graph illustrating a resistance variation of a phase-change memory unit according to example embodiments of the present invention;

FIG. 7 is a graph illustrating contents of ingredients in a phase-change material layer including carbon and irregularly distributed stabilizing metal;

FIG. 8 is a graph illustrating a resistance variation of a phase-change memory unit including the phase-change material layer in FIG. 7;

FIG. 9 is a graph illustrating a resistance variation of a phase-change memory unit including a phase-change material layer including nitrogen and irregularly distributed stabilizing metal;

FIG. 10 is a graph illustrating contents of ingredients in a phase-change material layer including nitrogen and uniformly distributed stabilizing metal;

FIG. 11 is a graph illustrating a graph illustrating a resistance variation of a phase-change memory unit including the phase-change material layer in FIG. 10;

FIG. 12 is a graph illustrating set resistance variation of a phase-change memory unit according to example embodiments of the present invention;

FIG. 13 is a graph illustrating driving resistances of the conventional phase-change memory device and a phase-change memory unit of the present invention;

FIG. 14 is a graph illustrating contents of ingredients in a phase-change material layer including uniformly distributed titanium as a stabilizing metal;

FIGS. 15A to 15I are cross sectional views illustrating a method of manufacturing a phase-change memory device in accordance with example embodiments of the present invention;

FIGS. 16A to 16C are cross-sectional views illustrating a method of manufacturing a phase-change memory device in accordance with example embodiments of the present invention; and

FIGS. 17A to 17C are cross-sectional views illustrating a method of manufacturing a phase-change memory device in accordance with example embodiments of the present invention.

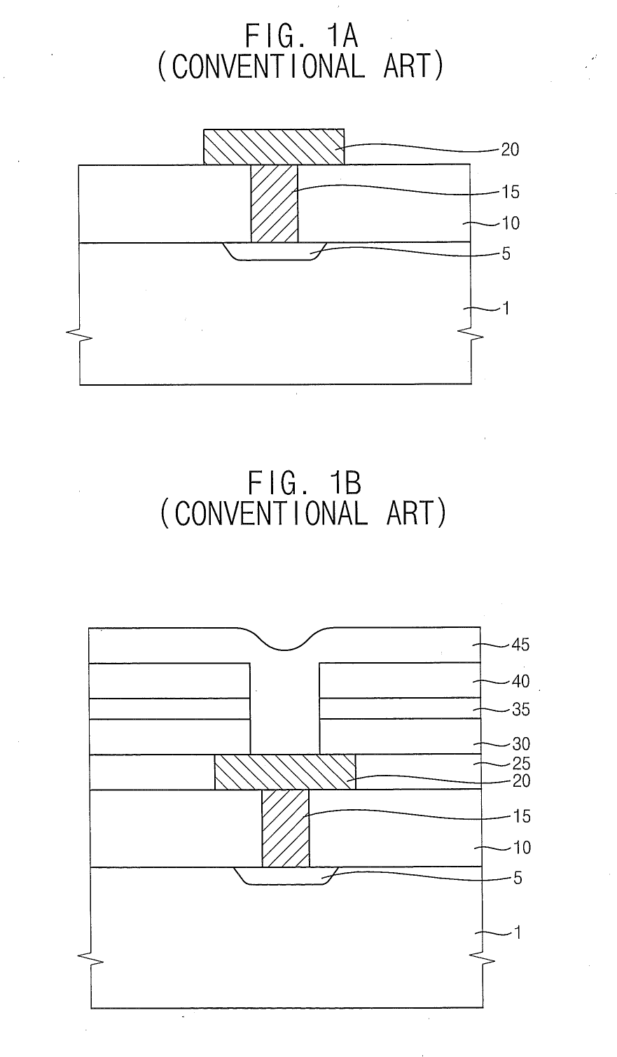

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Method of Manufacturing a Phase-Change Memory Unit

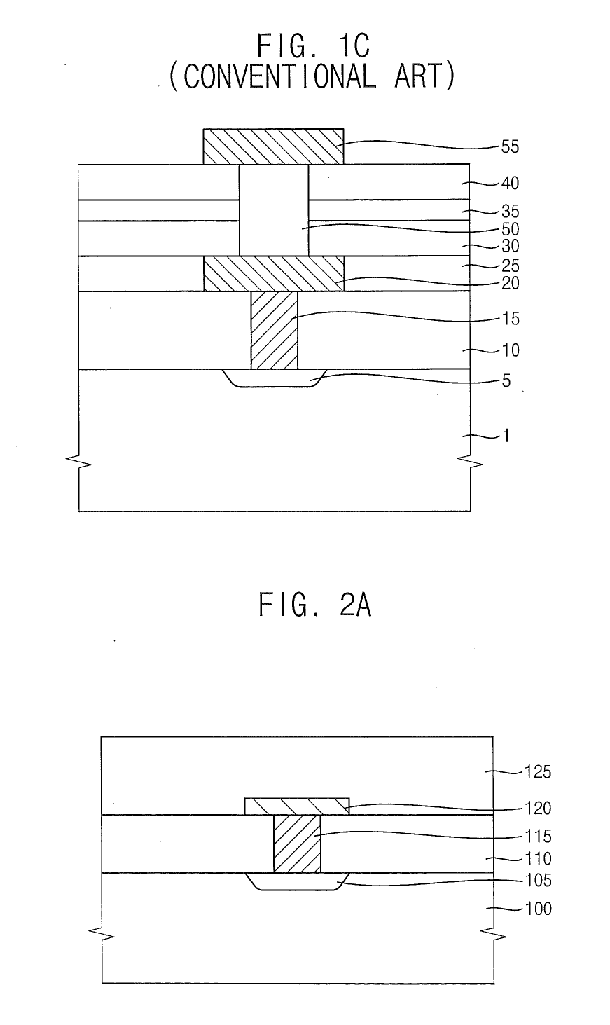

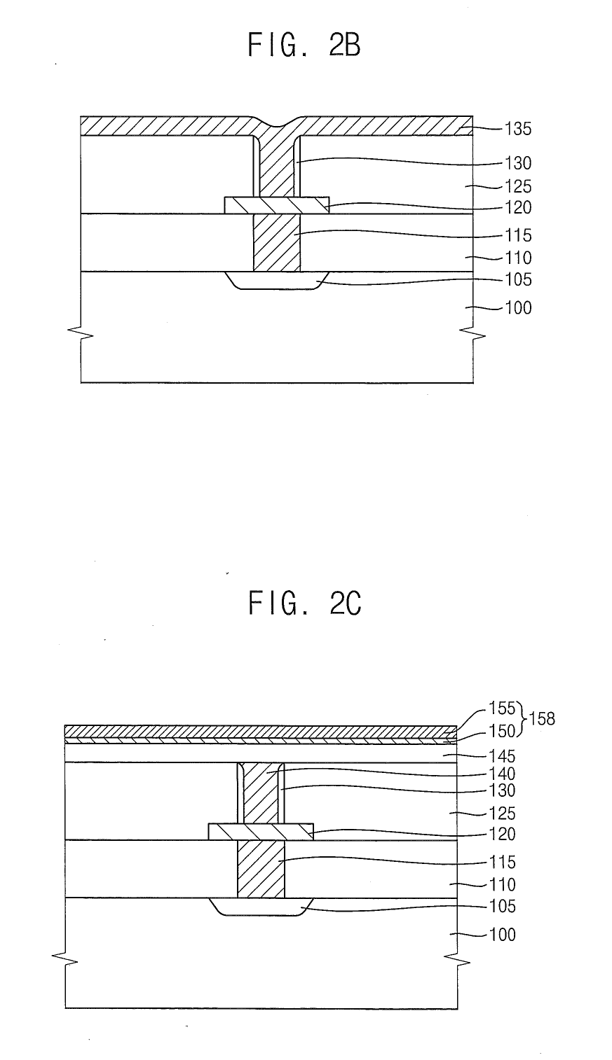

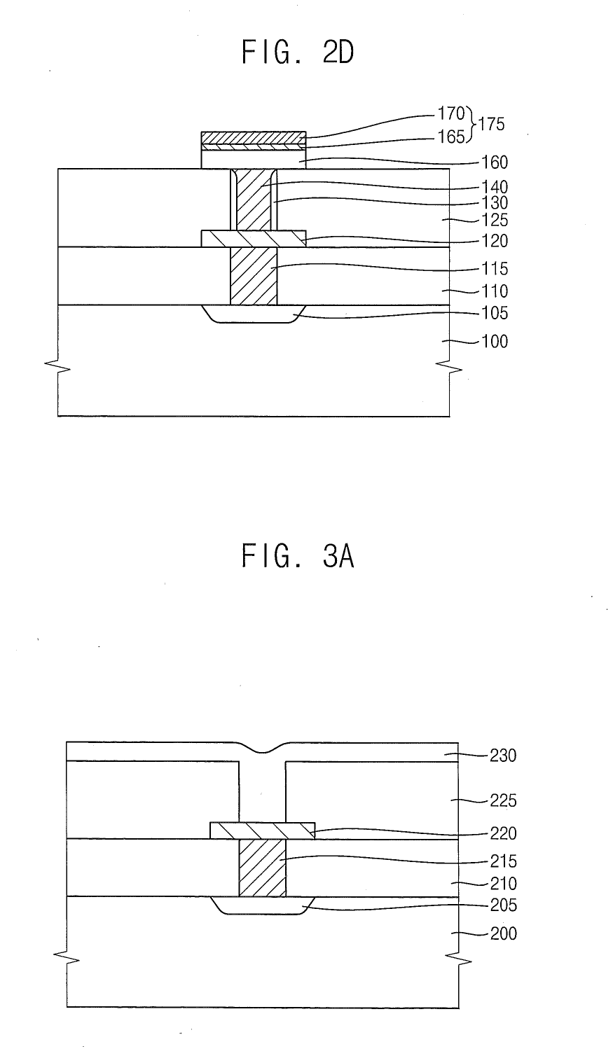

FIGS. 2A to 2D are cross-sectional views illustrating a method of manufacturing a phase-change memory unit in accordance with example embodiments of the present invention.

Referring to FIG. 2A, a contact region 105 is formed on a substrate 100. The contact region 105 may be formed at a portion of the substrate 100 by implanting impurities into the portion of the substrate 100. For example, the contact region 105 may be formed by an ion implantation process. The substrate 100 may include a semiconductor substrate or a single crystalline metal oxide substrate. For example, the substrate 100 may include a silicon substrate, a germanium substrate, a silicon-germanium substrate, a silicon-on-insulator (SOI) substrate, a germanium-on-insulator (GOI) substrate, a single crystalline aluminum oxide substrate, a single crystalline strontium titanium oxide substrate, etc.

In some example embodiments of the present invention, a lower structure may be provided on the substrate 100. The lower structure may include a conductive layer pattern, an insulation layer pattern, a pad, an electrode, a spacer, a gate structure and/or a transistor. The lower structure may be electrically connected to the contact region 105 of the substrate 100.

An insulating interlayer 110 is formed on the substrate 100 to cover the lower structure. The insulating interlayer 110 may have a predetermined height to sufficiently cover the lower structure and the contact region 105. The insulating interlayer 110 may be formed using an oxide. For example, the insulating interlayer 110 may be formed using silicon oxide such as undoped silicate glass (USG), spin on glass (SOG), flowable oxide (FOX), boro-phosphor silicate glass (BPSG), phosphor silicate glass (PSG), tetraethylortho silicate (TEOS), plasma enhanced-tetraethylortho silicate (PE-TEOS), high density plasma-chemical vapor deposition (HDP-CVD) oxide, etc. Further, the insulating interlayer 110 may be formed by a CVD process, a low pressure chemical vapor deposition (LPCVD) process, a plasma enhanced chemical vapor deposition (PECVD) process, an HDP-CVD process, etc.

After a first photoresist pattern (not illustrated) is formed on the insulating interlayer 110, the insulating interlayer 110 is partially etched using the first photoresist pattern as an etching mask. Thus, a contact hole (not illustrated) is formed through the insulating interlayer 110 to expose the contact region 105 of the substrate 100. The first photoresist pattern may be removed from the insulating interlayer 110 by an ashing process and/or a stripping process.

A first conductive layer (not illustrated) is formed on the exposed contact region 105 and the insulating interlayer 110 to fill up the contact hole. The first conductive layer may be formed using polysilicon doped with impurities, a metal or a metal compound. For example, the first conductive layer may be formed using tungsten (W), aluminum (Al), titanium (Ti), copper (Cu), tantalum (Ta), tungsten nitride (WN_{X}), titanium nitride (TiN_{X}), aluminum nitride (AlN_{X}), titanium aluminum nitride (TiAl_{X}N_{Y}), tantalum nitride (TaN_{X}), etc. Further, the first conductive layer may be formed by a sputtering process, a CVD process, an atomic layer deposition (ALD) process, an electron beam evaporation process, a pulsed laser deposition (PLD) process, etc. In some example embodiments, the first conductive layer may have a multi-layered structure that includes a metal film, a metal compound film and/or a doped polysilicon film.

The first conductive layer is partially removed until the insulating interlayer 110 is exposed so that a first pad 115 is formed on the contact region 105 to fill the contact hole. The first pad 115 may be formed by a chemical mechanical polishing (CMP) process and/or an etch-back process.

A second conductive layer (not illustrated) is formed on the first pad 115 and the insulating interlayer 110. The second conductive layer may be formed using a doped polysilicon, a metal and/or a metal compound. For example, the second conductive layer may be formed using tungsten, aluminum, titanium, copper, tantalum, tungsten nitride, titanium nitride, aluminum nitride, titanium aluminum nitride, tantalum nitride, etc. Additionally, the second conductive layer may be formed by a sputtering process, a CVD process, an ALD process, an electron beam evaporation process, a PLD process, etc. In some example embodiments, the second conductive layer may have a multi-layered structure that includes a metal film, a metal compound film and/or a doped polysilicon film.

After a second photoresist pattern (not illustrated) is formed on the second conductive layer, the second conductive layer is patterned using the second photoresist pattern as an etching mask. Thus, a second pad 120 is formed on the first pad 115 and a portion of the insulating interlayer 110 around the first pad 115. The second pad 120 may have a width substantially wider than that of the first pad 115. The second photoresist pattern may be removed from the second pad 120 by an ashing process and/or a stripping process.

An insulation structure 125 is formed on the insulating interlayer 110 to cover the second pad 120. The insulation structure 125 may include at least one oxide layer, at least one nitride layer and/or at least one oxynitride layer. In one example embodiment, the insulation structure 125 may include an oxide layer covering the second pad 120 and the insulating interlayer 110. In another example embodiment, the insulation structure 125 may include an oxide layer and a nitride layer sequentially formed on the second pad 120 and the insulating interlayer 110. In still another example embodiment, the insulation structure 125 may include a first oxide layer, a nitride layer and a second oxide layer successively formed on the insulating interlayer 110 to cover the second pad 120. In still another example embodiment, the insulation structure 125 may include a first oxide layer, an oxynitride layer and a second oxide layer. In still another example embodiment, the insulation structure 125 may include a first oxide layer, a second oxide layer, a first nitride layer, a second nitride layer; a first oxynitride layer and/or a second oxynitride layer alternately or sequentially formed on the insulating interlayer 110 to cover the second pad 120. Here, the first and the second oxide layers may be formed using silicon oxide, and the first and the second nitride layers may be formed using silicon nitride. Additionally, the first and the second oxynitride layers may be formed using silicon oxynitride or titanium oxynitride.

In some example embodiments of the present invention, the insulation structure 125 may include one oxide layer formed using an oxide such as USG, SOG, FOX, BPSG, PSG, TEOS, PE-TEOS, HDP-CVD oxide, etc.

Referring to FIG. 2B, a third photoresist pattern (not illustrated) is formed on the insulation structure 125, and then the insulation structure 125 is partially etched using the third photoresist pattern as an etching mask. Accordingly, an opening (not illustrated) is formed through insulation structure 125 to expose the second pad 120. The opening may have a width substantially narrower than that of the second pad 120. The third photoresist pattern may be removed from the insulation structure 125 by an ashing process and/or a stripping process.

An insulation layer (not illustrated) is formed on the insulation structure 125 and the second pad 120 to fill up the opening. The insulation layer may be formed using a material that has an etching selectivity relative to the insulation structure 125. For example, the insulation layer may be foiined using a nitride such as silicon nitride.

A spacer 130 is formed on a sidewall of the opening by partially etching the insulation layer. For example, the spacer 130 may be formed by an anisotropic etching process. The spacer 130 may adjust a width of a lower electrode 140 (see FIG. 2C) successively formed in the opening so that the lower electrode 140 may have a desired width due to the spacer 130. However, the spacer 130 may not be formed on the sidewall of the opening when the opening has a proper width for the lower electrode 140.

A lower electrode layer 135 is formed on the second pad 120 and the insulation structure 125 to sufficiently fill up the opening. The lower electrode layer 135 may be formed using doped polysilicon, a metal and/or a metal compound. For example, the lower electrode layer 135 may be formed using tungsten, aluminum, copper, tantalum, titanium, molybdenum, tungsten nitride, aluminum nitride, titanium nitride, tantalum nitride, molybdenum nitride (MoN_{X}), niobium nitride (NbN_{X}), titanium silicon nitride (TiSiN_{X}), titanium aluminum nitride (TiAlN_{X}), titanium boron nitride (TiBN_{X}), zirconium silicon nitride (ZrSiN_{X}), tungsten silicon nitride (WSiN_{X}), tungsten boron nitride (WBN_{X}), zirconium aluminum nitride (ZrAlN_{X}), molybdenum silicon nitride (MoSiN_{X}), molybdenum aluminum nitride (MoAlN_{X}), tantalum silicon nitride (TaSiN_{X}), tantalum aluminum nitride (TaAlN_{X}), etc. In some example embodiment, the lower electrode layer 135 may have a single layer structure including a doped polysilicon film, a metal film or a metal compound film. In other example embodiments, the lower electrode layer 135 may have a multilayer structure that includes a metal film, a metal compound film and/or a doped polysilicon film.

Referring to FIG. 2C, the lower electrode layer 135 is partially removed until the insulation structure 125 is exposed. Thus, the lower electrode 140 filling the opening is formed on the second pad 120. The lower electrode 140 may be formed by a CMP process and an etch-back process. The lower electrode 140 may be electrically connected to the contact region 105 of the substrate 100 through the second pad 120 and the first pad 115. Since the lower electrode 140 fills up the opening, the lower electrode 140 may have a contact structure, a plug structure, a pad structure, a column structure, a pillar structure, a polygonal pillar structure, etc. In some example embodiments, the lower electrode 140, the second pad 120 and/or the first pad 115 may include substantially the same materials. Alternatively, the lower electrode 140, the second pad 120 and/or the first pad 115 may include different materials one after another.

A preliminary phase-change material layer (not illustrated) is formed on the lower electrode 140 and the insulation structure 125. The preliminary phase-change material layer may be formed using a chalcogenide compound doped with carbon or a chalcogenide compound doped with carbon and nitrogen. Further, the preliminary phase-change material layer may be formed on the lower electrode 140 and the insulation structure 125 by a physical vapor deposition (PVD) process or a CVD process.

In some example embodiments, the preliminary phase-change material layer may be formed on the lower electrode 140 and the insulation structure 125 by a sputtering process using one target. For example, the preliminary phase-change material layer may be formed using a target that includes a chalcogenide compound doped with carbon. Alternatively, the preliminary phase-change material layer may be formed using a target including a chalcogenide compound doped with carbon under an atmosphere including nitrogen.

In other example embodiments, the preliminary phase-change material layer may be formed by a co-sputtering process simultaneously using at least two targets. For example, the preliminary phase-change material layer may be formed using a first target including carbon and a second target including a chalcogenide compound such as GST. Alternatively, the preliminary phase-change material layer may be formed simultaneously using a first target including carbon and a second target including a chalcogenide compound under an atmosphere including nitrogen. Additionally, the preliminary phase-change material layer may be formed simultaneously using a first target including carbon, a second target including germanium-tellurium, and a third target including antimony-tellurium. Furthermore, the preliminary phase-change material layer may be formed simultaneously using a first target including carbon, a second target including germanium-tellurium, and a third target including antimony-tellurium under an atmosphere including nitrogen.

When the preliminary phase-change material layer is formed by the sputtering process or the co-sputtering process, the preliminary phase-change material layer is changed into a phase-change material layer 145 by additionally using a target including a stabilizing metal. Accordingly, the phase-change material layer 145 may include a chalcogenide compound doped with carbon and the stabilizing metal or a chalcogenide compound doped with carbon, nitrogen and the stabilizing metal. Examples of the stabilizing metal may include titanium (Ti), nickel (Ni), zirconium (Zr), molybdenum (Mo), ruthenium (Ru), hafnium (Hf), tantalum (Ta), iridium (Ir), platinum (Pt), etc. These may be used alone or in a mixture thereof.

In some example embodiments, the preliminary phase-change material layer may be changed into the phase-change material layer 145 by an additional sputtering process using a target including a stabilizing metal. For example, the additional sputtering process may be performed on the preliminary phase-change material layer using the target including the stabilizing metal, thereby obtaining the phase-change material layer 145 on the lower electrode 140 and the insulation structure 125. The processes for forming the preliminary phase-change material layer and the phase-change material layer 145 may be performed in-situ under a vacuum atmosphere or an inactive gas atmosphere. Therefore, the phase-change material layer 145 may include a chalcogenide compound doped with carbon and the stabilizing metal or a chalcogenide compound doped with carbon, nitrogen and the stabilizing metal.

In some example embodiments; the preliminary phase-change material layer may be formed on the lower electrode 140 by the CVD process. For example, the preliminary phase-change material layer may be formed using a first source gas including germanium, a second source gas including antimony, a third source gas including tellurium and a reaction gas including carbon. Alternatively, the preliminary phase-change material layer may be formed using a first source gas including germanium, a second source gas including antimony, a third source gas including tellurium, a first reaction gas including carbon and a second reaction gas including nitrogen. Additionally, the preliminary phase-change material layer may be formed using a source gas including germanium, antimony and tellurium, and a reaction gas including carbon. Furthermore, the preliminary phase-change material layer may be formed using a source gas including germanium, antimony and tellurium, and a reaction gas including carbon and nitrogen.

When the preliminary phase-change material layer is formed on the lower electrode 140 and the insulation structure 125 by the CVD process, an additional source gas including a stabilizing metal may be used to change the preliminary phase-change material layer into the phase-change material layer 145.

In some example embodiments, an additional CVD process using a source gas including a stabilizing metal may be executed on the preliminary phase-change material layer such that the preliminary phase-change material layer may be changed into the phase-change material layer 145. The processes for forming the preliminary phase-change material layer and the phase-change material layer 145 may be performed in-situ under a vacuum atmosphere or an inactive gas atmosphere. Accordingly, the phase-change material layer 145 may include a chalcogenide compound doped with carbon and the stabilizing metal or a chalcogenide compound doped with carbon, nitrogen and the stabilizing metal.

In some example embodiments, the preliminary phase-change material layer may be changed into the phase-change material layer 145 by a stabilizing process after an upper electrode layer 158 is formed on the preliminary phase-change material layer.

Referring now to FIG. 2C, the upper electrode layer 158 is formed on the phase-change material layer 145. The upper electrode layer 158 includes a first upper electrode film 150 and a second upper electrode film 155. The second upper electrode film 155 may have a thickness substantially thicker than that of the first upper electrode film 150.

The first upper electrode film 150 may be formed using the stabilizing metal, and the second upper electrode film 155 may be formed using a metal compound. For example, the first upper electrode film 150 may be formed using titanium, nickel, zirconium, molybdenum, ruthenium, palladium, hafnium, tantalum, iridium, platinum, etc. These may be used alone or in a mixture thereof. Additionally, the second upper electrode film 155 may be formed using titanium nitride, nickel nitride, zirconium nitride, molybdenum nitride, ruthenium nitride, palladium nitride, hafnium nitride, tantalum nitride, iridium nitride, platinum nitride, tungsten nitride, aluminum nitride, niobium nitride, titanium silicon nitride, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc. These may be used alone or in a mixture thereof. The first and the second upper electrode films 150 and 155 may be formed by a sputtering process, a CVD process, an ALD process, an electron beam evaporation process, a PLD process, etc. In some example embodiments, the processes for forming the first and the second upper electrode films 150 and 155 may be performed in-situ.

When the preliminary phase-change material layer is formed by the CVD process as described above, the stabilizing process may be performed on the preliminary phase-change material layer after the upper electrode layer 158 is formed on the preliminary phase-change material layer. Thus, the preliminary phase-change material layer may be changed into the phase-change material layer 145 by the stabilizing process. For example, the upper electrode layer 158 and the preliminary phase-change material layer may be treated at a temperature of about 300° C. to about 800° C. for about 10 minutes to about 4 hours under an atmosphere including an inactive gas. The inactive gas may include a nitrogen gas, an argon gas, a helium gas, etc. In the stabilizing process for forming the phase-change material layer 145, the stabilizing metal included in the first upper electrode film 150 may be diffused into the preliminary phase-change material layer so that the phase-change material layer 145 may include a chalcogenide compound doped with the stabilizing metal. That is, the phase-change material layer 145 may include a chalcogenide compound doped with carbon and the stabilizing metal or a chalcogenide compound doped with carbon, nitrogen and the stabilizing metal.

In one example embodiment, the phase-change material layer 145 may include a chalcogenide compound doped with carbon and the stabilizing metal. For example, the phase-change material layer 145 may include a GST compound in accordance with the following chemical formula (1):

C_{A}M_{B}[Ge_{X}Sb_{Y}Te_{(100-X-Y)}]_{(100-A-B)} (1)

In the chemical formula (1), C denotes carbon and M indicates the stabilizing metal. The stabilizing metal may include titanium, nickel, zirconium, molybdenum, ruthenium, palladium, hafnium, tantalum, iridium and/or platinum. Additionally, 0.2≦A≦30.0, 0.1≦X≦15.0, 0.1≦X≦30.0 and 0.1≦Y≦90.0.

In another example embodiment, the phase-change material layer 145 may include a chalcogenide compound in which germanium in the chemical formula (1) is substituted with germanium and silicon (Si) or germanium and tin (Sn). For example, the phase-change material layer 145 may include a GST compound according to the following chemical formula (2):

C_{A}M_{B}[Ge_{X}Z_{(100-X)}Sb_{Y}Te_{(100-X-Y)}]_{(100-A-B)} (2)

In the chemical formula (2), Z includes silicon or tin, 0.2≦A≦30.0, 0.1≦b≦0.15, 0.1≦X≦80.0 and 0.1≦Y≦90.0.

In still another example embodiment, the phase-change material layer 145 may include a chalcogenide compound in which antimony in the chemical formula (1) is substituted with antimony and arsenic (As) or antimony and bismuth (Bi). For example, the phase-change material layer 145 may include a GST compound according to the following chemical formula (3):

C_{A}M_{B}[Ge_{X}Sb_{Y}T_{100-Y)}Te_{(100-X-Y)}]_{(100-A-B)} (3)

In the chemical formula (3), T includes arsenic or bismuth, 0.2≦A≦30.0, 0.1≦B≦15.0, 0.1≦X≦90.0 and 0.1≦Y≦80.0.

In still another example embodiment, the phase-change material layer 145 may include a chalcogenide compound in which tellurium in the chemical formula (1) is substituted with antimony and selenium (Se). For example, the phase-change material layer 145 may include a GST compound according to the following chemical formula (4):

C_{A}M_{B}[Ge_{X}Sb_{Y}Q_{(100-X-Y)}]_{(100-A-B)} (4)

In the chemical formula (4), Q includes antimony and selenium, 0.2≦A≦30.0, 0.1≦X≦90.0 and 0.1≦Y≦90.0. Further, Q indicates Sb_{D}Te_{(100-D)}, and 0.1≦D≦80.0.

In still another example embodiment, the phase-change material layer 145 may include a chalcogenide compound doped with carbon, nitrogen and the stabilizing metal. For example, the phase-change material layer 145 may include a GST compound in accordance with the following chemical formula (5):

C_{A}M_{B}N_{C}[Ge_{X}Sb_{Y}Te_{(100-X-Y)}]_{(100-A-B-C)} (5)

In the chemical formula (5), C means carbon, N indicates nitrogen and M denotes the stabilizing metal. Additionally, 0.2≦A≦30.0, 0.1≦B≦15.0 and 0.1≦C≦10.0. Furthermore, 0.1≦X≦30.0 and 0.1≦Y≦90.0.

In still another example embodiment, the phase-change material layer 145 may include a chalcogenide compound in which germanium in the chemical formula (5) is substituted with germanium and silicon (Si) or germanium and tin (Sn). For example, the phase-change material layer 145 may include a GST compound according to the following chemical formula (6):

C_{A}M_{B}N_{C}[Ge_{X}Z_{(100-X)}Sb_{Y}Te_{(100-X-Y)}]_{(100-A-B-C)} (6)

In the chemical formula (6), Z includes silicon or tin, 0.2≦A≦30.0, 0.1≦B≦15.0, 0.1≦X≦80.0 and 0.1≦Y≦90.0.

In still another example embodiment, the phase-change material layer 145 may include a chalcogenide compound in which antimony in the chemical formula (5) is substituted with antimony and arsenic (As) or antimony and bismuth (Bi). For example, the phase-change material layer 145 may include a GST compound according to the following chemical formula (7):

C_{A}M_{B}N_{C}[Ge_{X}Sb_{Y}T_{(100-Y)}Te_{(100-X-Y)}]_{(100-A-B-C)} (7)

In the chemical formula (7), T includes arsenic or bismuth, 0.2≦A≦30.0, 0.1≦X≦90.0 and 0.1≦Y≦80.0.

In still another example embodiment, the phase-change material layer 145 may include a chalcogenide compound in which tellurium in the chemical formula (5) is substituted with antimony and selenium (Se). For example, the phase-change material layer 145 may include a GST compound according to the following chemical formula (8):

C_{A}M_{B}N_{C}[Ge_{X}Sb_{Y}Q_{(100-X-Y)}]_{(100-A-B)} (8)

In the chemical formula (8), Q includes antimony and selenium, 0.2≦A≦30.0, 0.1≦B≦0.15, 0.1≦X≦90.0 and 0.15≦X≦90.0. Further, Q indicates Sb_{D}Te_{(100-D)}, and 0.1≦D≦80.0.

In some example embodiments of the present invention, the phase-change material layer 145 may include a chalcogenide compound that includes more than two of the chalcogenide compounds in accordance with the above chemical formulae (1) to (8).

Referring to FIG. 2D, after a fourth photoresist pattern (not illustrated) is formed on the upper electrode layer 158, the second upper electrode film 155, the first upper electrode film 150 and the phase-change material layer 145 are patterned using the fourth photoresist pattern as an etching mask. Accordingly, a phase-change material layer pattern 160 and an upper electrode 175 are formed on the lower electrode 140 and the insulation structure 125. The upper electrode 175 includes a first upper electrode film pattern 165 and a second upper electrode film pattern 170 successively formed on the phase-change material layer pattern 160.

Since the conventional phase-change memory device includes a phase-change material layer of a GST compound without the stabilizing metal, a ser resistance of the conventional phase-change memory device may increase. Particularly, the conventional phase-change memory device may be stuck in a reset state because a threshold voltage (Vth) of the conventional phase-change memory device may be considerably increased. However, the phase-change memory unit of the present invention includes the phase-change material layer pattern containing the chalcogenide compound doped with carbon, the stabilizing metal and/or nitrogen so that a set resistance of the phase-change memory unit may effectively decrease and the phase-change memory unit may have a durability substantially more than twice times longer than that of the conventional phase-change memory device. Further, the first upper electrode film pattern including the stabilizing metal is provided on the phase-change material layer pattern such that an adhesion strength between the phase-change material layer pattern and the upper electrode may be efficiently increased and an ohmic contact between the phase-change material layer pattern and the upper electrode may be easily ensured. As a result, the phase-change memory unit may have greatly improved electrical characteristics, reliability, durability, etc.

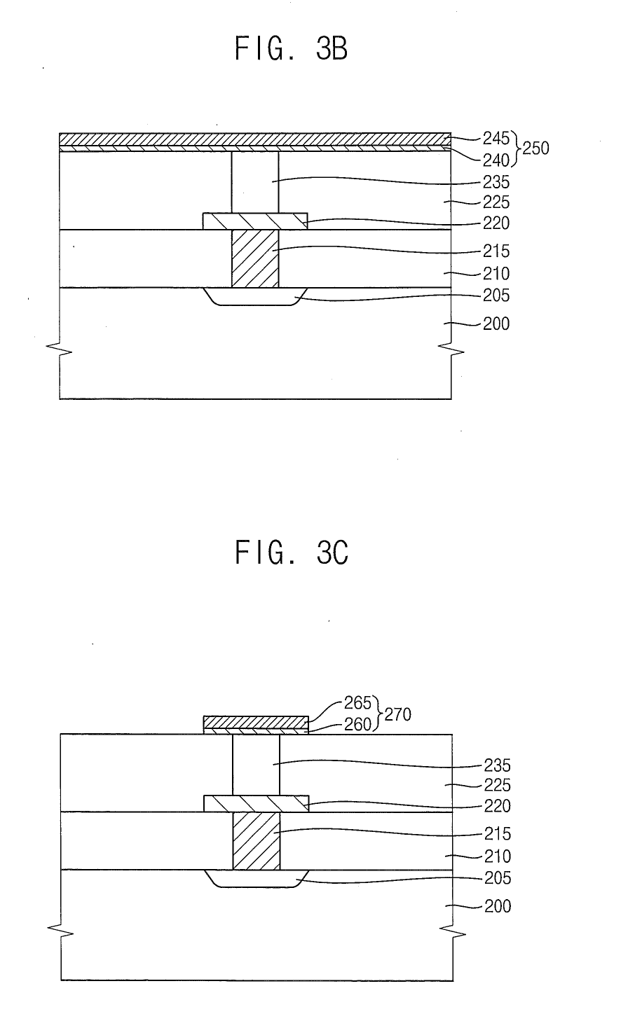

FIGS. 3A to 3C are cross-sectional views illustrating a method of manufacturing a phase-change memory unit in accordance with example embodiments of the present invention.

Referring to FIG. 3A, after a contact region 205 is formed on a substrate 200, a lower structure (not illustrated) is formed on the substrate 200. The lower electrode may be electrically connected to the contact region 205. The substrate 200 may include a semiconductor substrate or a single crystalline metal oxide substrate, and the lower structure may include a conductive layer pattern, an insulation layer pattern, a pad, an electrode, a spacer, a gate structure and/or a transistor.

An insulating interlayer 210 covering the lower structure is foamed on the substrate 200. The insulating interlayer 210 may be formed using an oxide by a CVD process, an LPCVD process, a PECVD process, an HDP-CVD process, etc.

A first photoresist pattern (not illustrated) is formed on the insulating interlayer 210, and then the insulating interlayer 210 is partially etched using the first photoresist pattern as an etching mask. Accordingly, a contact hole (not illustrated) is formed through the insulating interlayer 210 to expose the contact region 205. After forming the contact hole, the first photoresist pattern may be removed from the insulating interlayer 210 by an ashing process and/or a stripping process.

A conductive layer (not illustrated) is formed on the exposed contact region 205 and the insulating interlayer 210 to fill up the contact hole. The conductive layer may be formed using polysilicon doped with impurities, a metal or a metal compound by a sputtering process, a CVD process, an ALD process, an electron beam evaporation process, a PLD process, etc. In some example embodiments, the conductive layer may have a multi-layered structure including a metal film, a metal compound film and/or a doped polysilicon film.

The conductive layer is partially removed until the insulating interlayer 210 is exposed such that a pad 215 filling the contact hole is formed on the contact region 205. The pad 215 may be formed by a CMP process and/or an etch-back process.

A lower electrode layer (not illustrated) is formed on the pad 215 and the insulating interlayer 210. The lower electrode layer may be formed using a doped polysilicon, a metal and/or a metal compound by a sputtering process, a CVD process, an ALD process, an electron beam evaporation process, a PLD process, etc. For example, the lower electrode layer may be formed using tungsten, aluminum, copper, tantalum, titanium, molybdenum, tungsten nitride, aluminum nitride, titanium nitride, tantalum nitride, molybdenum nitride, niobium nitride, titanium silicon nitride, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc. These may be used alone or in a mixture thereof. In some example embodiments, the lower electrode layer may have a multi-layered structure that includes a metal film, a metal compound film and/or a doped polysilicon film.

A second photoresist pattern (not illustrated) is formed on the lower electrode layer, and then the lower electrode layer is partially etched using the second photoresist pattern as an etching mask. Accordingly, a lower electrode 220 is formed on the pad 215 and a portion of the insulating interlayer 210 around the pad 215. The lower electrode 220 may be electrically connected to the contact region 205 through the pad 215. After forming the lower electrode 220, the second photoresist pattern may be removed from the lower electrode 220 by an ashing process and/or a stripping process.

An insulation structure 225 covering the lower electrode 220 is formed on the insulating interlayer 210. The insulation structure 225 may include at least one oxide layer, at least one nitride layer and/or at least one oxynitride layer. For example, the insulation structure 225 may include an oxide layer covering the lower electrode 220 or may include an oxide layer and a nitride layer sequentially formed on the lower electrode 220 and the insulating interlayer 210. Alternatively, the insulation structure 225 may include a first oxide layer, a nitride layer and a second oxide layer, or may include a first oxide layer, a second oxide layer, a first nitride layer, a second nitride layer, a first oxynitride layer and/or a second oxynitride layer alternately or sequentially formed on the insulating interlayer 110 to cover the second pad 120. In some example embodiments, the first and the second oxide layers may be formed using silicon oxide, and the first and the second nitride layers may be formed using silicon nitride. Further, the first and the second oxynitride layers may be formed using silicon oxynitride or titanium oxynitride.

Referring now to FIG. 3A, after a third photoresist pattern (not illustrated) is formed on the insulation structure 225, the insulation structure 225 is partially etched using the third photoresist pattern as an etching mask. Hence, an opening (not illustrated) is formed through insulation structure 225 to expose the lower electrode 220. The opening may have a width substantially narrower than that of the lower electrode 220. The third photoresist pattern may be removed from the insulation structure 225 by an ashing process and/or a stripping process after forming the opening.

In some example embodiments, a preliminary phase-change material layer filling the opening is formed on the lower electrode 220 and the insulation structure 225, and then the preliminary phase-change material layer is changed into a phase-change material layer 230 by a process substantially the same as the process described with reference to FIG. 2C. As described above, the preliminary phase-change material layer may include a chalcogenide compound doped with carbon or a chalcogenide compound doped with carbon and nitrogen. Further, the phase-change material layer 230 may include a chalcogenide compound doped with carbon and a stabilizing metal, or a chalcogenide compound doped with carbon, nitrogen and a stabilizing metal. That is, the phase-change material layer 230 may include a chalcogenide compound having a composition in accordance with the above chemical formulae (1) to (8). Alternatively, the phase-change material layer 230 may include more than two of the chalcogenide compound according to the above chemical formulae (1) to (8).

In some example embodiments, a preliminary phase-change material layer may be formed on the lower electrode 220 and the insulation structure 225 to fill up the opening, and then the preliminary phase-change material layer may be changed into the phase-change material layer 230 by a stabilizing process substantially the same as that described with reference to FIG. 2C after forming an upper electrode layer 250 (see FIG. 3B) on the preliminary phase-change material layer.

Referring to FIG. 3B, the preliminary phase-change material layer or the phase-change material layer 230 is partially removed until the insulation structure 225 is exposed. Accordingly, a preliminary phase-change material layer pattern or a phase-change material layer pattern 235 is formed on the lower electrode 220. Since the preliminary phase-change material layer pattern or the phase-change material layer pattern 235 fills up the opening, the preliminary phase-change material layer pattern or the phase-change material layer pattern 235 may have a width substantially smaller than that of the lower electrode 220.

In some example embodiment, a spacer (not illustrated) may be additionally formed on a sidewall of the opening before forming the preliminary phase-change material layer or the phase-change material layer 230. The spacer may adjust a width of the preliminary phase-change material layer pattern or the phase-change material layer pattern 235. However, the spacer may not be formed on the sidewall of the opening when the opening has a proper width for the preliminary phase-change material layer or the phase-change material layer 230.

The upper electrode layer 250 is formed on the insulation structure 225 and the phase-change material layer pattern 235 or the preliminary phase-change material layer pattern. The upper electrode layer 250 includes a first upper electrode film 240 and a second upper electrode film 245. The first upper electrode film 240 may be formed using the stabilizing metal, and the second upper electrode film 245 may be formed using a metal compound. For example, the first upper electrode film 240 may be formed using titanium, nickel, zirconium, molybdenum, ruthenium, palladium, hafnium, tantalum, iridium and/or platinum. The second upper electrode film 245 may be formed using titanium nitride, nickel nitride, zirconium nitride, molybdenum nitride, ruthenium nitride, palladium nitride, hafnium nitride, tantalum nitride, iridium nitride, platinum nitride, tungsten nitride, aluminum nitride, niobium nitride, titanium silicon nitride, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride and/or tantalum aluminum nitride. The first and the second upper electrode films 240 and 245 may be formed by a sputtering process, a CVD process, an ALD process, an electron beam evaporation process, a PLD process, etc.

When the preliminary phase-change material layer is formed by a CVD process as described above, the stabilizing process may be executed on the preliminary phase-change material layer pattern after the upper electrode layer 250 is formed on the preliminary phase-change material layer pattern so as to change the preliminary phase-change material layer pattern into the phase-change material layer pattern 235. For example, the upper electrode layer 250 and the preliminary phase-change material layer pattern may be treated at a temperature of about 300° C. to about 800° C. for about 10 minutes to about 4 hours under an atmosphere including an inactive gas. In the stabilizing process for forming the phase-change material layer pattern 235, the stabilizing metal included in the first upper electrode film 240 may be diffused into the preliminary phase-change material layer pattern so that the phase-change material layer pattern 235 may include a chalcogenide compound doped with the stabilizing metal. As a result, the phase-change material layer pattern 235 may include a chalcogenide compound doped with carbon and the stabilizing metal or a chalcogenide compound doped with carbon, nitrogen and the stabilizing metal.

Referring to FIG. 3C, after a fourth photoresist pattern (not illustrated) is formed on the upper electrode layer 250, the second upper electrode film 245, the first upper electrode film 240 are patterned using the fourth photoresist pattern as an etching mask. Thus, an upper electrode 270 is formed on the phase-change material layer pattern 235 and the insulation structure 225. The upper electrode 270 includes a first upper electrode film pattern 260 and a second upper electrode film pattern 265 sequentially formed on the phase-change material layer pattern 235 and the insulation structure 225.

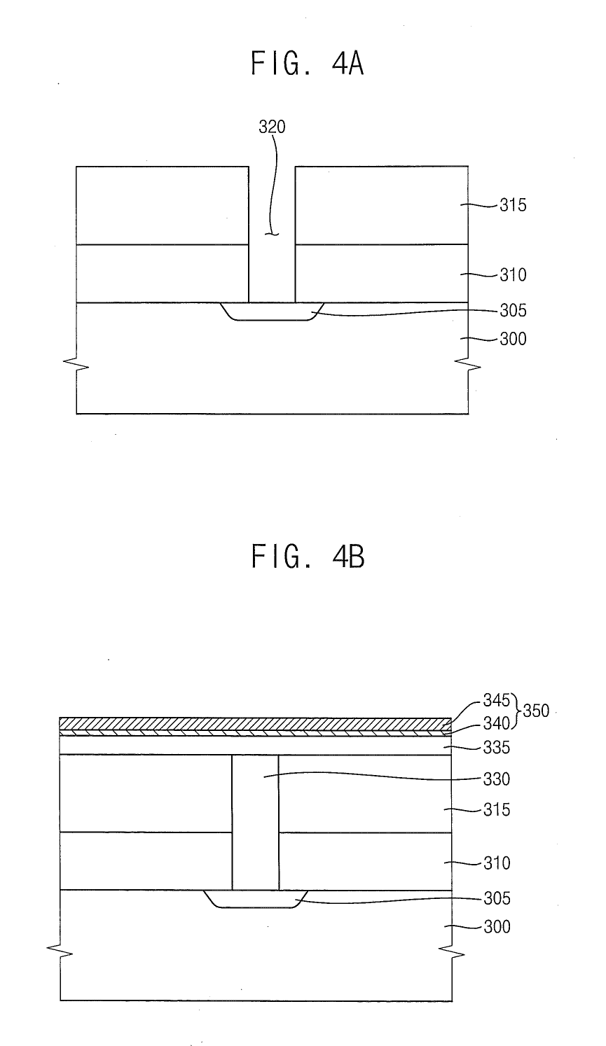

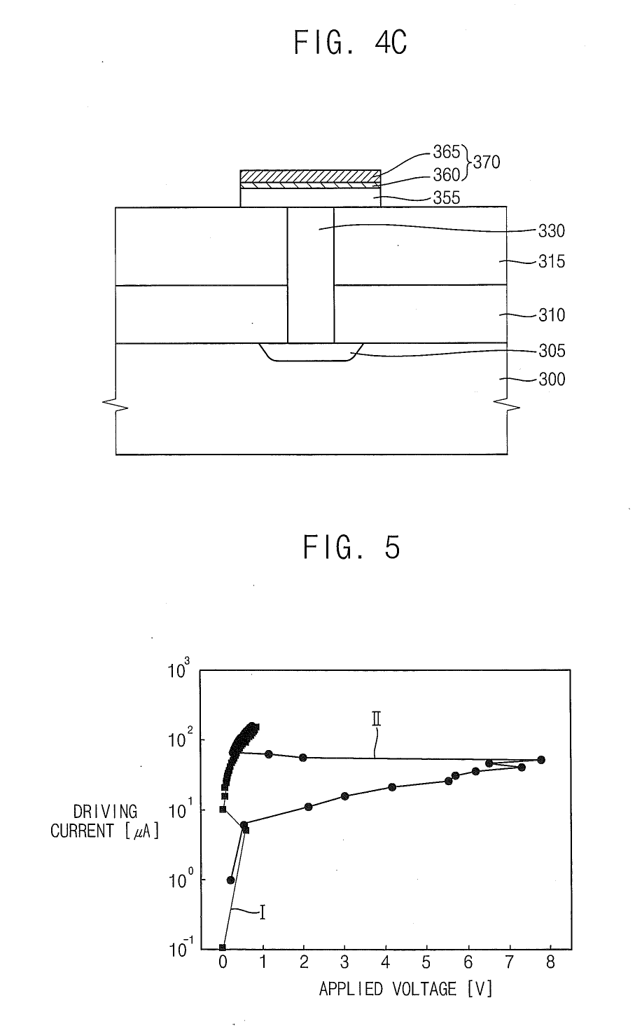

FIGS. 4A to 4C are cross-sectional views illustrating a method of manufacturing a phase-change memory unit in accordance with example embodiments of the present invention.

Referring to FIG. 4A, a lower structure (not illustrated) is formed on a substrate 300 having a contact region 305, and then an insulating interlayer 310 is formed on the substrate 300 to cover the lower structure and the contact region 305. The insulating interlayer 310 may be formed using an oxide by a CVD process, an LPCVD process, a PECVD process, an HDP-CVD process, etc.

An insulation structure 315 is formed on the insulating interlayer 310. The insulation structure 315 may include at least one oxide layer, at least one nitride layer and/or at least one oxynitride layer.

After a first photoresist pattern (not illustrated) is formed on the insulation structure 315, the insulation structure 315 and the insulating interlayer 310 are partially etched using the first photoresist pattern as an etching mask. Hence, an opening 320 exposing the contact region 305 is formed through the insulation structure 315 and the insulating interlayer 310. After forming the opening 320, the first photoresist pattern may be removed from the insulation structure 315 by an ashing process and/or a stripping process.

Referring to FIG. 4B, a diode 330 filling the opening 320 is formed on the contact region 305. For example, the diode 330 may include polysilicon formed by a selective epitaxial growth (SEG) process. The diode 330 may have a height substantially the same as a depth of the opening 320. Thus, upper faces of the diode 330 and the insulation structure 315 may be on a same plane. That is, the diode 330 may have a thickness substantially the same as a total thickness of the insulating interlayer 310 and the insulation structure 315.

A preliminary phase-change material layer is formed on the diode 330 and the insulation structure 315 using a chalcogenide compound doped with carbon or a chalcogenide compound doped with carbon and nitrogen as described above.

In some example embodiments, the preliminary phase-change material layer is formed on the diode 330, and then preliminary phase-change material layer is changed into a phase-change material layer 335 by a process substantially the same as the process described with reference to FIG. 2C. Thus, the phase-change material layer 335 may include a chalcogenide compound having a composition in accordance with the above chemical formulae (1) to (8). Namely, the phase-change material layer 335 may include a chalcogenide compound doped with carbon and a stabilizing metal, or a chalcogenide compound doped with carbon, nitrogen and a stabilizing metal. Alternatively, the phase-change material layer 335 may include more than two of the chalcogenide compound in accordance with the above chemical formulae (1) to (8).

In some example embodiments, a preliminary phase-change material layer may be formed on the diode 330 and the insulation structure 315 by a CVD process, and then the preliminary phase-change material layer may be changed into the phase-change material layer 335 by a stabilizing process substantially the same as that described with reference to FIG. 2C after forming an upper electrode layer 350 on the preliminary phase-change material layer. Here, the phase-change material layer 335 may also include the chalcogenide compound doped with carbon and the stabilizing metal, or the chalcogenide compound doped with carbon, nitrogen and the stabilizing metal.

Referring now to FIG. 4B, an upper electrode layer 350 including a first upper electrode film 340 and a second upper electrode film 345 is formed on the insulation structure 315 and the phase-change material layer 335 or the preliminary phase-change material layer. The first and the second upper electrode films 340 and 345 may be formed using the stabilizing metal and a metal compound, respectively. Further, the first and the second upper electrode films 340 and 345 may be formed by a sputtering process, a CVD process, an ALD process, an electron beam evaporation process, a PLD process, etc.

When the preliminary phase-change material layer is formed by the CVD process as described above, the stabilizing process may be performed on the preliminary phase-change material layer after the upper electrode layer 350 is formed on the preliminary phase-change material layer, thereby changing the preliminary phase-change material layer into the phase-change material layer 335. For example, the upper electrode layer 350 and the preliminary phase-change material layer may be treated at a temperature of about 300° C. to about 800° C. for about 10 minutes to about 4 hours under an atmosphere including an inactive gas.

Referring to FIG. 4C, after a second photoresist pattern (not illustrated) is formed on the upper electrode layer 350, the second upper electrode film 345, the first upper electrode film 340 and the phase-change material layer 335 are partially etched using the second photoresist pattern as an etching mask. Accordingly, a phase-change material layer pattern 355 and the upper electrode 370 are formed on the diode 330 and a portion of the insulation structure 315 around the diode 330. The upper electrode 370 includes a first upper electrode film pattern 360 and a second upper electrode film pattern 365 successively formed on the phase-change material layer pattern 355.

FIG. 5 is a graph illustrating a driving current of a conventional phase-change memory device including a phase-change material layer of a GST compound without a stabilizing metal. The driving current of the conventional phase-change memory device is measured with respect to a voltage applied thereto. In FIG. 5, “I” denotes a driving current of the conventional phase-change memory device before generating a failure of the conventional phase-change memory device. Additionally, “II” represents a driving current of the conventional phase-change memory device after generating the failure of the conventional phase-change memory device.

As illustrated in FIG. 5, when operation cycles of a writing operation, a reading operation and an erasing operation are performed on the conventional phase-change memory device, the failure of the conventional phase-change memory device occurs because a threshold voltage (Vth) of the conventional phase-change memory device increases. For example, data may not be repeatedly recorded into the conventional phase-change memory device. Although this failure of the conventional further may be recoverable, this failure may deteriorate operations and reliability of the conventional phase-change memory device.

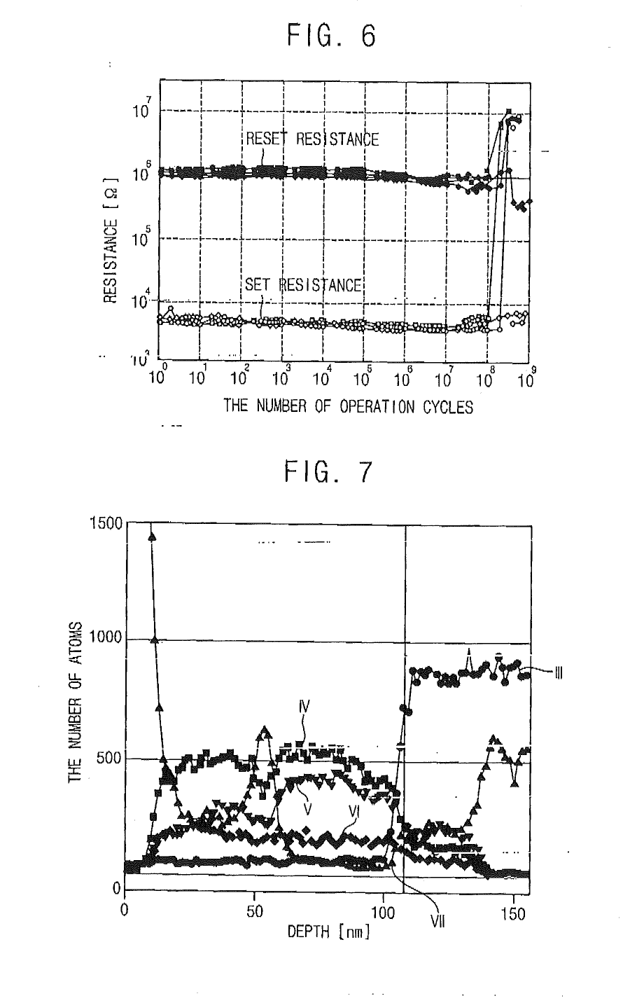

FIG. 6 is a graph illustrating a resistance variation of a phase-change memory unit according to example embodiments of the present invention. The resistance variation of the phase-change memory unit is measured relative to the number of operation cycles including a writing operation, a reading operation and an erasing operation. In FIG. 6, the phase-change memory unit includes a phase-change material layer pattern of a chalcogenide compound doped with carbon and titanium as a stabilizing metal. Additionally, a first upper electrode film pattern of the phase-change memory unit includes titanium, and a second upper electrode film pattern of the phase-change memory unit includes titanium nitride. The phase-change material layer pattern and the first upper electrode film pattern are treated by a stabilizing process performed at a temperature of about 400° C. for about 30 minutes.

Referring to FIG. 6, a failure such as irregular resistance is generated in the phase-change memory unit after the operation cycles are performed by about 1×10⁸ times to about 5×10⁸ times. In the conventional phase-change memory device, however, a failure is generated after performing the operation cycles by about 1×10⁴ times to about 5×10⁶ times. Therefore, the phase-change memory unit of the present invention may have durability greatly larger than that of the conventional phase-change memory device by about 100 times to about 10,000 times. Since the phase-change memory unit of the present invention includes the phase-change material layer containing the distributed stabilizing metal, the phase-change memory unit may have considerably enhanced durability and improved set resistance. Further, the phase-change memory unit of the present invention may have stable set resistance and reset resistance while repeating the operation cycles. Particularly, the phase-change memory unit of the present invention has more improved durability as a content of the stabilizing metal in the phase-change material layer increases.

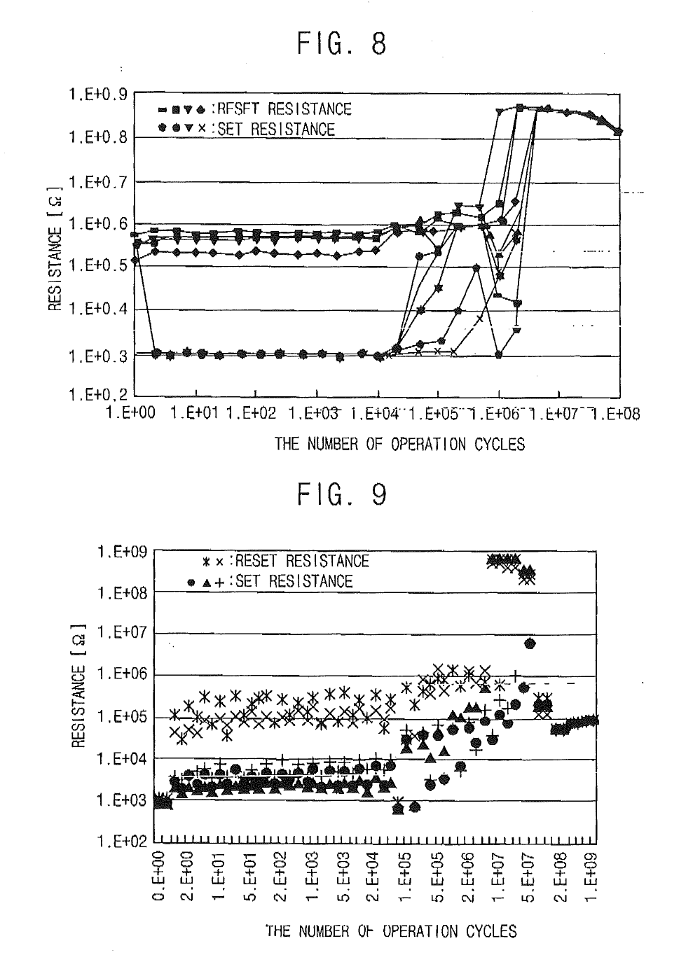

FIG. 7 is a graph illustrating contents of ingredients in a phase-change material layer including carbon and irregularly distributed stabilizing metal. FIG. 8 is a graph illustrating a resistance variation of a phase-change memory unit including the phase-change material layer in FIG. 7. The resistance variation of the phase-change memory unit is measured with respect to the number of operation cycles.

In FIG. 7, “III” represents a content of silicon (Si) in the phase-change material layer and “IV” denotes a content of tellurium (Te) in the phase-change material layer. Additionally, “V” and “VI” indicate contents of antimony (Sb) and germanium (Ge) in the phase-change material layer, respectively. Furthermore, “VII” means a content of titanium as a stabilizing metal in the phase-change material layer. The phase-change memory unit includes the phase-change material layer, a first upper electrode film of titanium, and a second upper electrode film of titanium nitride. A stabilizing process is performed on the phase-change material layer and the first upper electrode film at a relatively low temperature of about 200° C.

As illustrated in FIG. 7, titanium corresponding to the stabilizing metal is not uniformly distributed into the phase-change material layer when the stabilizing process is carried out at the relatively low temperature. For example, titanium is accumulated in the phase-change material layer by a depth of about 50A to about 150A. When the phase-change memory unit includes such phase-change material layer, the phase-change memory unit has unstable set resistance and reset resistance as the number of operation cycles increases so that a failure occurs in the phase-change memory unit as illustrated in FIG. 8. Thus, the phase-change memory unit including the phase-change material layer containing the irregularly distributed stabilizing metal may have durability substantially similar to that of a phase-change memory unit including a phase-change material layer without a stabilizing metal.

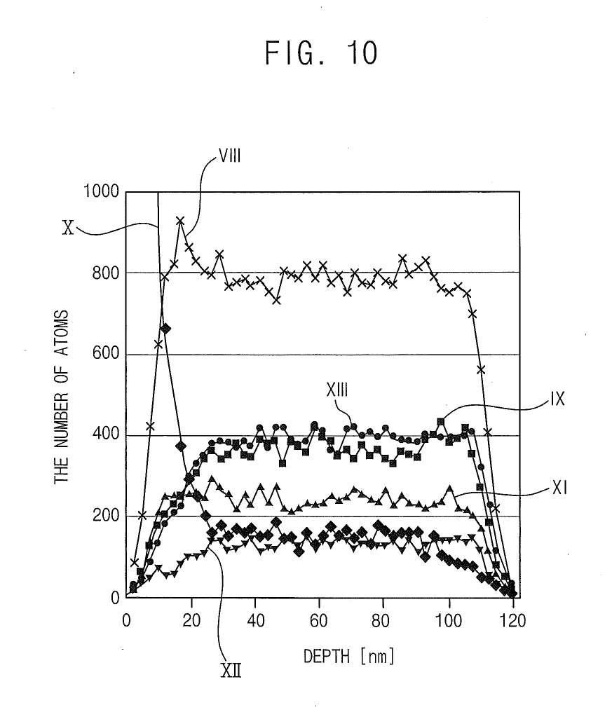

FIG. 9 is a graph illustrating a resistance variation of a phase-change memory unit including a phase-change material layer including nitrogen and irregularly distributed stabilizing metal. In FIG. 9, the resistance variation of the phase-change memory unit is measured with respect to the number of operation cycles. Further, the phase-change material layer includes a chalcogenide compound containing titanium as a stabilizing metal.

Referring to FIG. 9, the phase-change memory unit including the phase-change material layer has unstable set resistance and reset resistance after repeating the operation cycles by about 1×10⁵ times, thereby causing a failure in the phase-change memory unit. This result of the phase-change memory unit may be substantially similar to that of the phase-change memory unit in FIG. 8.

FIG. 10 is a graph illustrating contents of ingredients in a phase-change material layer including nitrogen and uniformly distributed stabilizing metal. FIG. 11 is a graph illustrating a resistance variation of a phase-change memory unit including the phase-change material layer in FIG. 10. The resistance variation of the phase-change memory unit is measured relative to the number of operation cycles.

In FIG. 10, “VIII” means a content of silicon in the phase-change material layer, “IX” denotes a content of antimony in the phase-change material layer, and “X” indicates a content of titanium as a stabilizing metal in the phase-change material layer. Further, “XI” represents a content of tellurium in the phase-change material layer, “XII” means a content of nitrogen in the phase-change material layer, and “XIII” indicates a content of germanium in the phase-change material layer. The phase-change memory unit includes the phase-change material layer, a first upper electrode film of titanium, and a second upper electrode film of titanium nitride. A stabilizing process is performed on the phase-change material layer and the first upper electrode film at a relatively low temperature of about 400° C. for about 30 minutes under a nitrogen atmosphere.

Referring to FIG. 10, titanium is uniformly distributed in the phase-change material layer irrespective of a depth of the phase-change material layer. Since the phase-change memory unit includes this phase-change material layer, the phase-change memory unit has desired resistance variation in accordance with applied current as illustrated in FIG. 11. That is, a crystalline structure of desired portion of the phase-change material layer is changed into an amorphous state from a crystal state, and thus the phase-change memory unit may have improved driving characteristics.

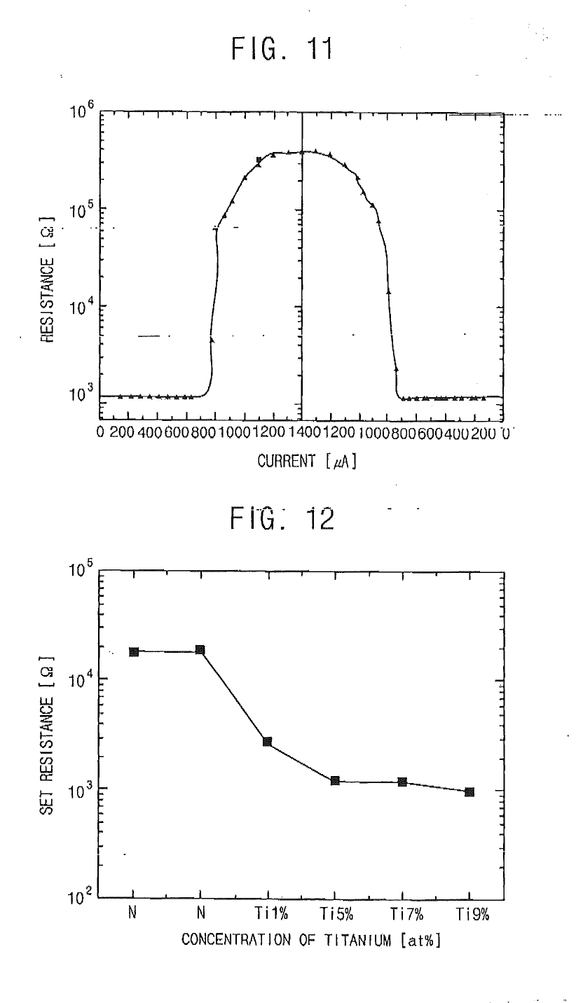

FIG. 12 is a graph illustrating set resistance variation of a phase-change memory unit according to example embodiments of the present invention. In FIG. 12, the set resistance variation of the phase-change memory unit is measured with respect to a doping concentration of a stabilizing metal.

Referring to FIG. 12, the phase-change memory unit has stably reduced set resistance as a content of titanium as the stabilizing metal in the phase-change material layer increases. Thus, the phase-change memory unit may have increased sensing margin to ensure improved reliability.

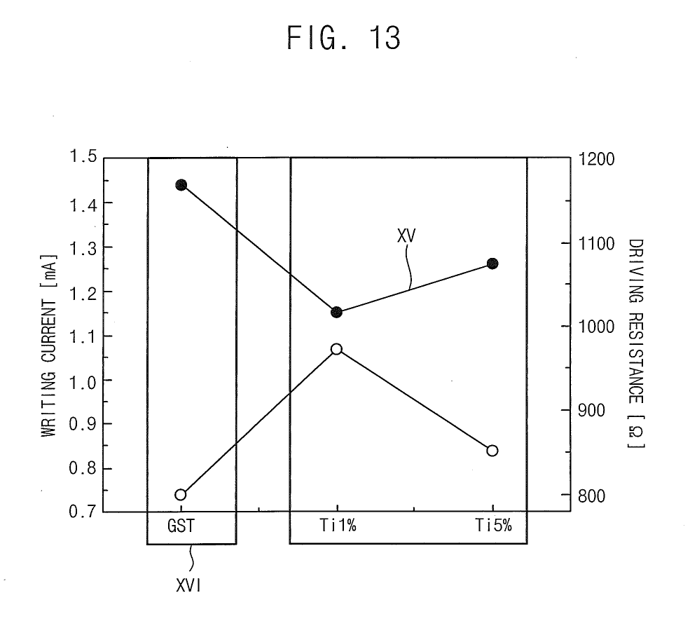

FIG. 13 is a graph illustrating driving resistances of the conventional phase-change memory device and a phase-change memory unit of the present invention. In FIG. 13, the driving resistances of the conventional phase-change memory device and the phase-change memory unit of the present invention are measured with respect to writing current. Additionally, “XV” indicates writing current variations of the conventional phase-change memory device and the phase-change memory unit of the present invention, and “XVI” means driving resistance variations of the conventional phase-change memory device and the phase-change memory unit of the present invention. The phase-change memory unit of the present invention includes a phase-change material layer containing a GST compound doped with a stabilizing metal.

Referring to FIG. 13, the phase-change memory unit of the present invention has writing effectively reduced writing current in comparison with that of the conventional phase-change memory device. Further, the phase-change memory unit of the present invention has relatively increased driving resistance comparing to that of the conventional phase-change memory device. Therefore, the phase-change memory unit may have improved electrical characteristics when the phase-change material layer includes a chalcogenide compound containing a stabilizing metal.

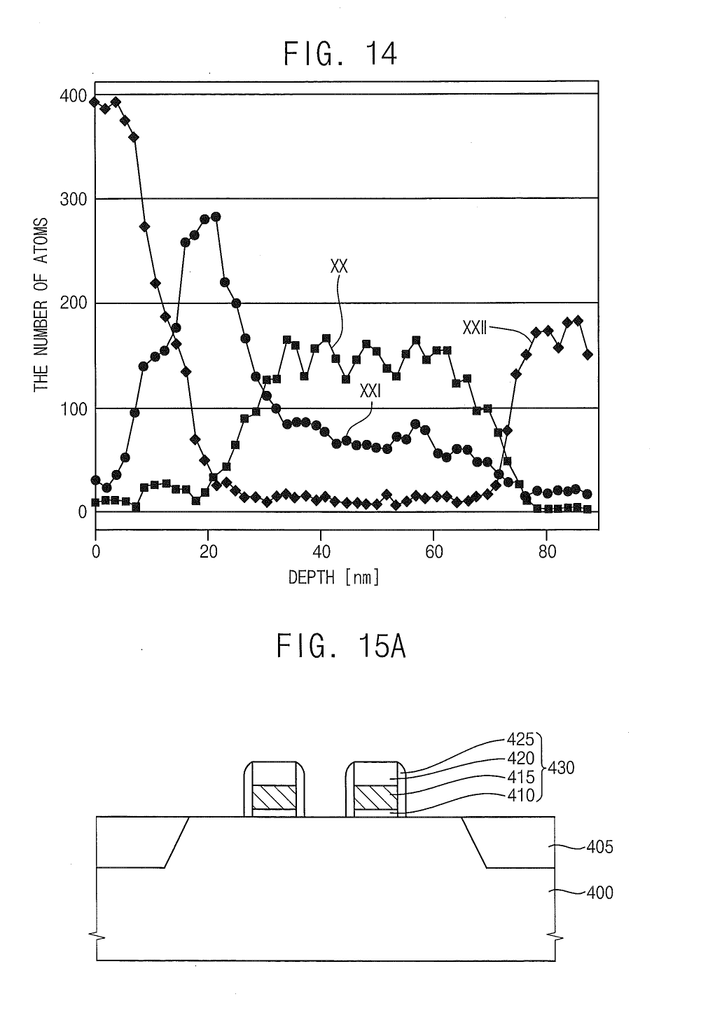

FIG. 14 is a graph illustrating contents of ingredients in a phase-change material layer including uniformly distributed tantalum as a stabilizing metal. A phase-change memory unit includes the phase-change material layer, a first upper electrode film of tantalum, and a second upper electrode film of titanium nitride. A stabilizing process is executed at a temperature of about 400° C. for about 30 minutes under a nitrogen atmosphere. In FIG. 14, “XX” represents a content of tellurium in the phase-change material layer, “XXI” denotes a content of tantalum in the phase-change material layer, and “XXII” indicates a content of titanium in the phase-change material layer, which is diffused from the second upper electrode film.

Referring to FIG. 14, tantalum is regularly distributed in the phase-change material layer after performing the stabilizing process. The phase-change memory unit includes the phase-change material layer so that the phase-change memory may have improved durability and reliability.

As described above, the phase transition of the phase-change material layer may be stably ensured because the phase-change material layer includes the chalcogenide compound doped with the stabilizing metal. Additionally, the phase-change material layer may have increased resistance and crystalline temperature. When the phase-change memory unit includes the phase-change material layer, the phase-change memory unit may have considerably reduced set resistance and enhanced durability. Further, the phase-change memory unit may have enlarged sensing margin and reduced driving current.

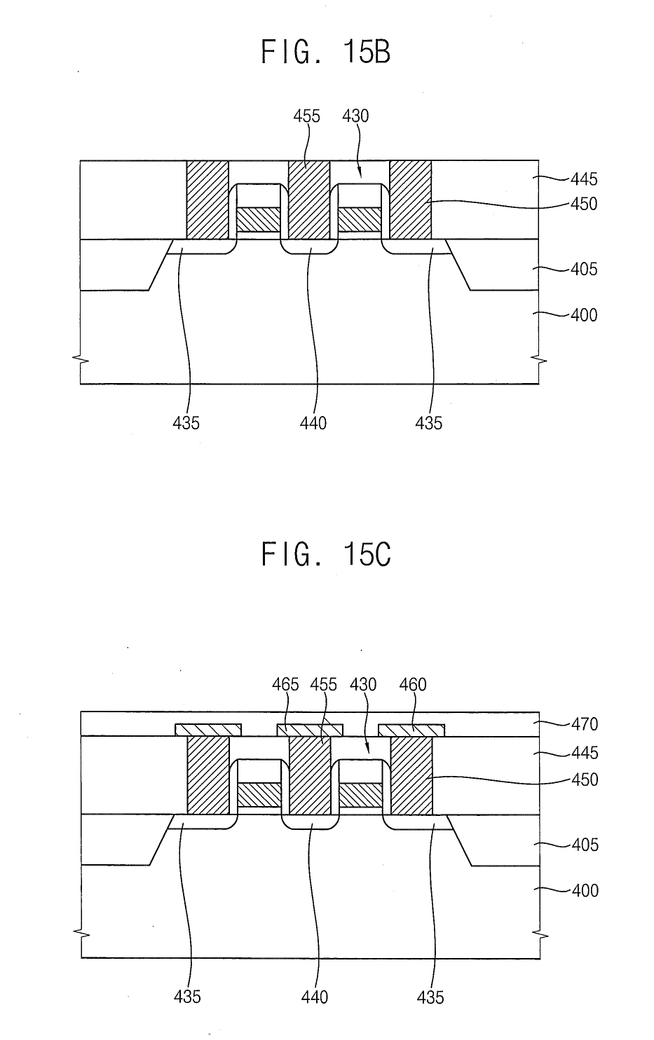

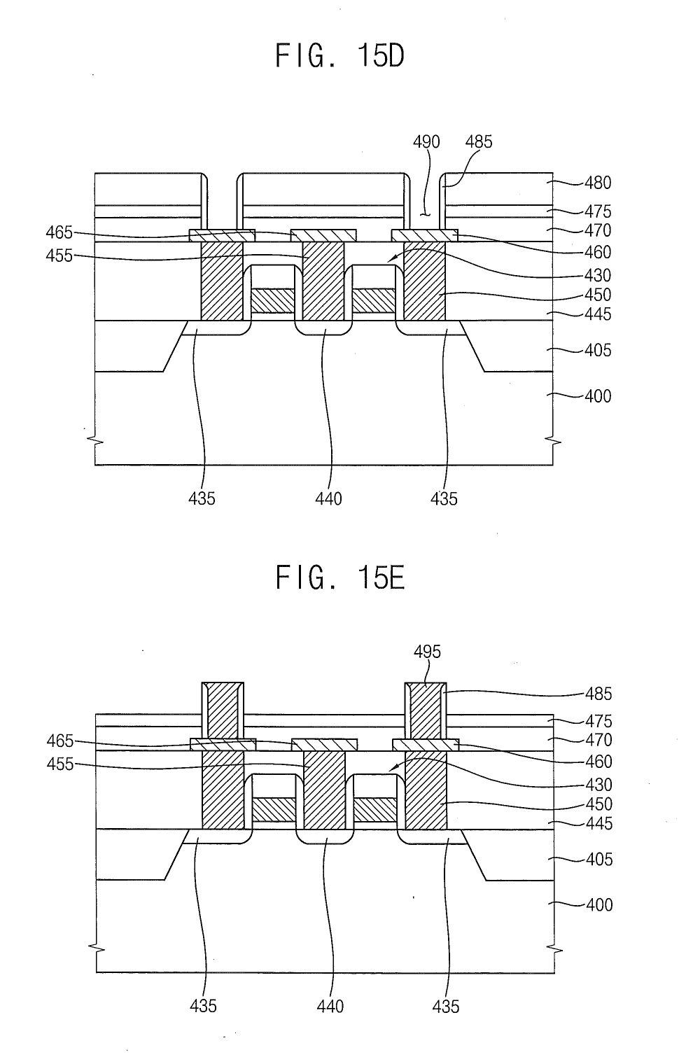

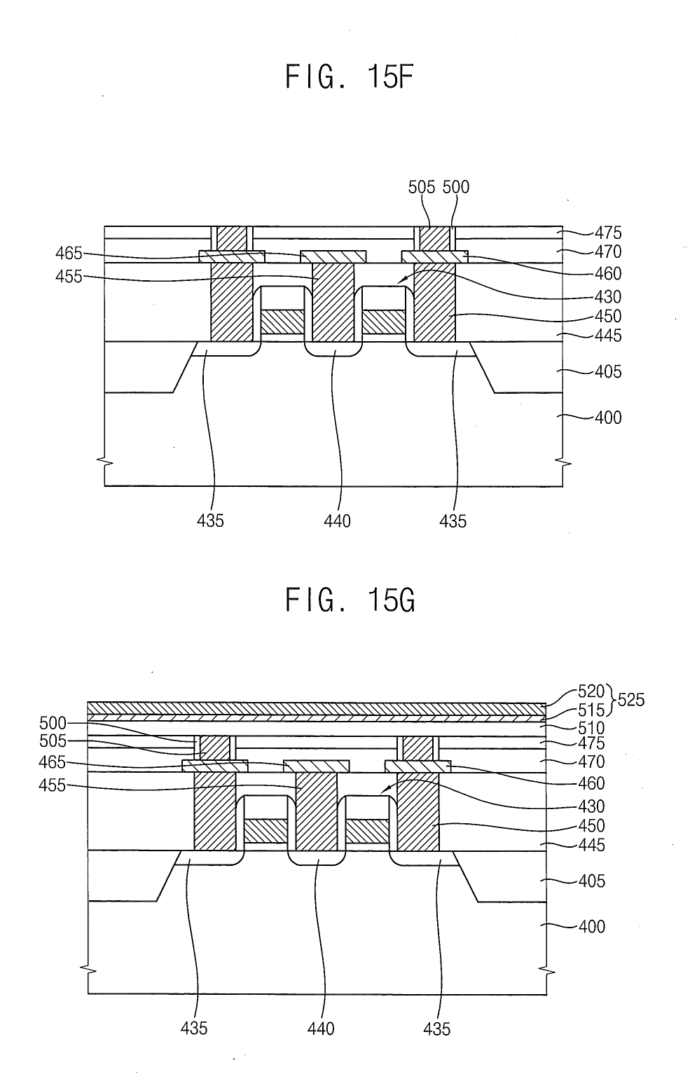

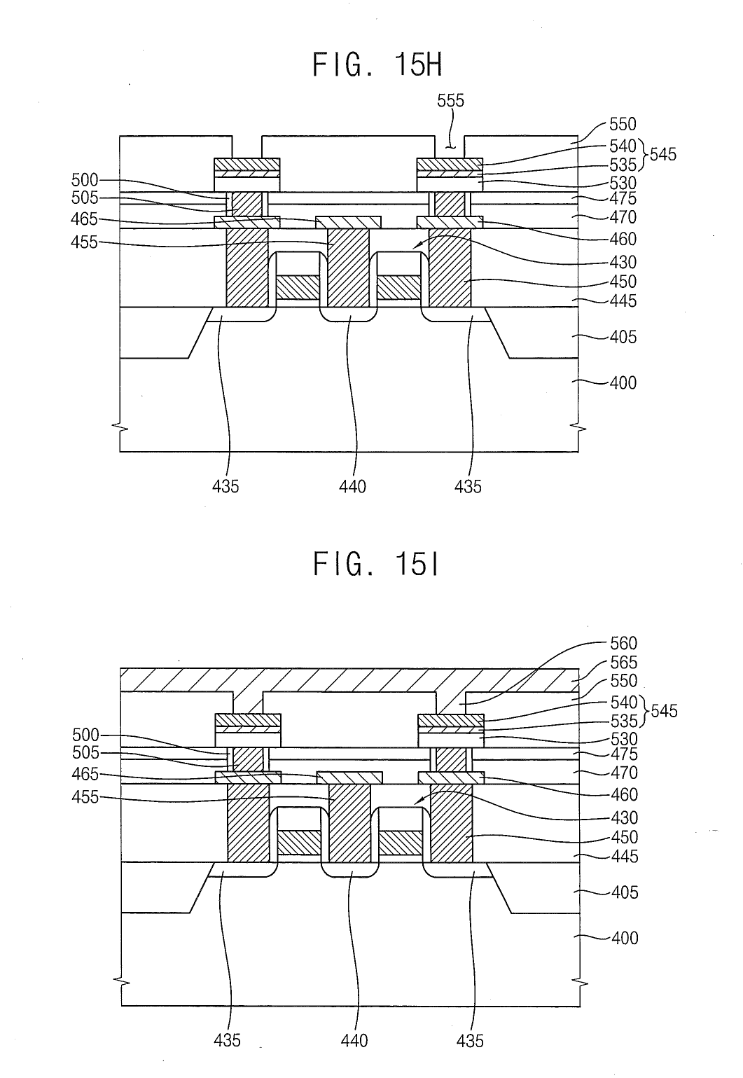

FIGS. 15A to 15I are cross-sectional views illustrating a method of manufacturing a phase-change memory device in accordance with example embodiments of the present invention.

Referring to FIG. 15A, an isolation layer 405 is formed on a substrate 400 by an isolation process. The isolation layer 405 may be formed using an oxide by a thermal oxidation process or a shallow trench isolation (STI) process. The substrate 400 may include a single crystalline metal oxide substrate or a semiconductor substrate such as a silicon substrate, a germanium substrate, a GOI substrate, an SOI substrate, etc. In accordance with a formation of the isolation layer 405, the substrate 100 is divided into an active region and a field region.

A gate insulation layer (now illustrated), a gate conductive layer (not illustrated) and a gate mask layer (not illustrated) are successively formed on the substrate 400. The gate insulation layer may be formed using an oxide or a metal oxide. For example, the gate insulation layer may be formed using silicon oxide, aluminum oxide, zirconium oxide, hafnium oxide, tantalum oxide, etc. The gate conductive layer may be formed using polysilicon doped with impurities, a metal or a metal compound. For example, the gate conductive layer may be formed using tungsten, aluminum, copper, titanium, tantalum, tungsten nitride, aluminum nitride, titanium nitride, tantalum nitride, titanium aluminum nitride, etc. The gate mask layer may be formed using a material having an etching selectivity relative to the gate insulation layer and the gate conductive layer. For example, the gate mask layer may be formed using silicon nitride or silicon oxynitride.

The gate mask layer, the gate conductive layer and the gate insulation layer are patterned by a photolithography process, thereby forming a gate insulation layer pattern 410, a gate conductive layer pattern 415 and a gate mask 420 on the active region of the substrate 400. In another example embodiment, the gate mask layer may be etched to form the gate mask 420 on the gate conductive layer, and then the gate conductive layer and the gate insulation layer may be patterned using the gate mask 420 to thereby form the gate insulation layer pattern 410 and the gate conductive layer pattern 415 on the substrate 400.

After a lower insulation layer (not illustrated) is formed on the substrate 400 to cover the gate mask 420, the lower insulation layer is partially etched to form a gate spacer 425 on sidewalls of the gate insulation layer pattern 410, the gate conductive layer pattern 415 and the gate mask 420. The gate spacer 425 may include a nitride such as silicon nitride. Accordingly, a gate structure 430 is provided on the substrate 400. The gate structure 425 includes the gate insulation layer pattern 410, the gate conductive layer pattern 415, the gate mask 420 and the gate spacer 425.

Referring to FIG. 15B, impurities are implanted into portions of the active region of the substrate 400 adjacent to the gate structure 430, so that a first contact region 435 and a second contact region 440 are formed at the portions of the substrate 400. The first and the second contact regions 121 and 124 may be formed by an ion implantation process. A lower electrode 163 (see FIG. 15F) may be electrically connected to the first contact region 435, and a lower wiring 465 (see FIG. 15C) may be electrically connected to the second contact region 440.

A lower insulating interlayer 445 is formed on the substrate 400 to sufficiently cover the gate structure 430. The lower insulating interlayer 445 may be formed using an oxide by a CVD process, a PECVD process, an LPCVD process, an HDP-CVD process, etc. For example, the lower insulating interlayer 445 may be formed using PSG, BPSG, USG, SOG, TEOS, PE-TEOS, FOX, HDP-CVD oxide, etc. In an example embodiment, the lower insulating interlayer 445 may be planarized by a planarization process. For example, the lower insulating interlayer 445 may have a level surface by a CMP process and/or an etch-back process.

The lower insulating interlayer 445 is partially etched by a photolithography process so that a first contact hole (not illustrated) and a second contact hole (not illustrated) are formed through the lower insulating interlayer 445. The first and the second contact holes expose the first and the second contact regions 435 and 440, respectively.

A first lower conductive layer (not illustrated) is formed on the lower insulating interlayer 445 to fill up the first and the second contact holes. The first lower conductive layer may be formed using a metal, a metal compound and/or doped polysilicon. For example, the first lower electrode layer may be formed using tungsten, aluminum, copper, titanium, tantalum, tungsten nitride, aluminum nitride, titanium nitride, tantalum nitride, titanium aluminum nitride, etc. These can be used alone or in a mixture thereof. Additionally, the first lower electrode layer may be formed by a sputtering process, a CVD process, an LPCVD process, an ALD process, an electron beam evaporation process, a PLD process, etc.

The first lower conductive layer is partially removed until the lower insulating interlayer 445 is exposed such that a first pad 450 and a second pad 455 are formed through the lower insulating interlayer 445. The first pad 450 filling the first contact hole is formed on the first contact region 435, and the second pad 455 filling the second contact hole is positioned on the second contact region 440.

Referring to FIG. 15C, a second lower conductive layer (not illustrated) is formed on the first pad 450, the second pad 455 and the lower insulating interlayer 445. The second lower conductive layer may be formed using a metal, a metal compound and/or doped polysilicon. For example, the second lower electrode layer may be formed using tungsten, aluminum, copper, titanium, tantalum, tungsten nitride, aluminum nitride, titanium nitride, tantalum nitride, titanium aluminum nitride, etc. These may be used alone or in a mixture thereof. Further, the second lower electrode layer may be formed by a sputtering process, a CVD process, an LPCVD process, an ALD process, an electron beam evaporation process, a PLD process, etc.

The second lower conductive layer is patterned by a photolithography process to form a third pad 460 and the lower wiring 465. The third pad 460 is formed on the first pad 450 and the lower wiring 465 is positioned on the second pad 455. Thus, the third pad 460 may be electrically connected to the first contact region 435 through the first pad 450, and the lower wiring 465 may be electrically contacted to the second contact region 440 through the second pad 455. In some example embodiments, the lower wiring 465 may include a bit line. Further, the third pad 460 and the lower wiring 465 may have widths substantially wider than those of the first and the second pads 450 and 455, respectively.

A first insulation layer 470 is formed on the lower insulating interlayer 445 to cover the third pad 460 and the lower wiring 465. The first insulation layer 470 may be formed using an oxide such as PSG, BPSG, USG, SOG, TEOS, PE-TEOS, FOX, HDP-CVD oxide, etc. The first insulation layer 470 may be formed by a CVD process, a PECVD process, an LPCVD process, an HDP-CVD process, etc. In an example embodiment, an upper portion of the first insulation layer 470 may be planarized by a CMP process and/or an etch-back process so as to ensure a level upper face of the first insulation layer 470.

In some example embodiments, the first insulation layer 470 may be formed using an oxide substantially the same as that of the lower insulating interlayer 445. In other example embodiments, the first insulation layer 470 and the lower insulating interlayer 445 may be formed using different oxides, respectively.

Referring to FIG. 15D, a second insulation layer 475 and a sacrificial layer 480 are sequentially formed on the first insulation layer 470. The sacrificial layer 480 may be formed using an oxide substantially the same as or substantially similar to that of the first insulation layer 470, whereas the second insulation layer 475 may be formed using a material having an etching selectivity relative to the first insulation layer 470 and the sacrificial layer 480. For example, the sacrificial layer 480 may be formed using an oxide such as PSG, BPSG, USG, SOG, TEOS, PE-TEOS, FOX, HDP-CVD oxide, etc, whereas the second insulation layer 475 may be formed using silicon nitride or silicon oxynitride. Further, the sacrificial layer 480 may be formed by a CVD process, a PECVD process, an LPCVD process, an HDP-CVD process, etc. The second insulation layer 475 may be formed by a CVD process, a PECVD process, an LPCVD process, etc.

In some example embodiments, the first and the second insulation layers 470 and 475 may serve together as a mold structure for forming the lower electrode 505. Further, the first and the second insulation layers 470 and 475 may protect underlying structures formed on the substrate 400 in successive processes for forming the lower electrode 505. The sacrificial layer 480 may also serve as the mold structure for forming the lower electrode 505. However, the sacrificial layer 480 will be removed from the second insulation layer 475 after forming the lower electrode 505. A thickness of the first insulation layer 470 and a thickness of the sacrificial layer 480 may be substantially larger than that of the second insulation layer 475.

The sacrificial layer 480, the second insulation layer 475 and the first insulation layer 470 are partially etched by a photolithography process. Accordingly, an opening 490 is formed through the first insulation layer 470, the second insulation layer 475 and the sacrificial layer 480. The opening 490 exposes the third pad 460.

After an upper insulation layer (not illustrated) is formed on the exposed third pad 460, a sidewall of the opening 490 and the sacrificial layer 480, the upper insulation layer is partially etched to thereby form a preliminary spacer 485 on the sidewall of the opening 490. The upper insulation layer may be formed using a nitride such as silicon nitride, and the preliminary spacer 485 may be formed by an anisotropic etching process. The preliminary spacer 485 may reduce a width of the opening 490 to advantageously adjust a critical dimension of the lower electrode 505 formed in the opening 490. After forming the preliminary spacer 485 on the sidewall of the opening 490, the third pad 460 is exposed again through the opening 490.

Referring to FIG. 15E, a first conductive layer (not illustrated) is formed on the exposed third pad 460 and the sacrificial layer 480 to fill up the opening 490. The first conductive layer may be formed using a metal and/or a metal compound. For example, the first conductive layer may be formed using iridium, ruthenium, platinum, palladium, tungsten, titanium, tantalum, aluminum, titanium nitride, tantalum nitride, molybdenum nitride, niobium nitride, titanium silicon nitride, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc. These may be used alone or in a mixture thereof. Additionally, the first conductive layer may be formed by a sputtering process, a CVD process, a PECVD process, an electron beam evaporation process, an ALD process, a PLD process, etc.

The first conductive layer is partially removed until the sacrificial layer 480 is exposed so that a preliminary lower electrode 495 is formed on the third pad 460 to completely fill up the opening 490. The preliminary spacer 485 is positioned between the sidewall of the opening 490 and the preliminary lower electrode 495. The preliminary lower electrode 495 may be formed by a CMP process and/or an etch-back process.

After a formation of the preliminary lower electrode 495, the sacrificial layer 480 is removed from the second insulation layer 475. The sacrificial layer 480 may be removed by a wet etching process using an etching solution including fluoride or a dry etching process using an etching gas containing fluoride. In the etching process for removing the sacrificial layer 480, the second insulation layer 475 may effectively protect the underlying structures formed on the substrate 400. When the sacrificial layer 480 is removed, upper portions of the preliminary lower electrode 495 and the preliminary spacer 485 are upwardly protruded from the second insulation layer 475.

Referring to FIG. 15F, the upper portions of the preliminary lower electrode 495 and the preliminary spacer 485 are removed to form the lower electrode 505 and a spacer 500 on the third pad 460. The spacer 500 and the lower electrode 505 may be formed by a CMP process and/or an etch-back process. In formation of the spacer 500 and the lower electrode 505, the second insulation layer 475 may serve as an etching stop layer for protecting the underlying structure on the substrate 400. The lower electrode 505 may electrically make contact with the first contact region 435 through the third pad 460 and first pad 450. The spacer 500 may adjust the width of the lower electrode 505 to a desired width. In other example embodiments, the processes for forming the spacer 500 may be advantageously omitted when the opening 490 has a desired width for the lower electrode 505.

Referring to FIG. 15G, a preliminary phase-change material layer (not illustrated) is formed on the lower electrode 505, the spacer 500 and the second insulation layer 475. The preliminary phase-change material layer may be formed using a chalcogenide compound doped with carbon or carbon and nitrogen by a sputtering process, a CVD process, an ALD process, etc.

The preliminary phase-change material layer is changed into a phase-change material layer 510 by doping a stabilizing metal into the preliminary phase-change material layer. Such process for forming the phase-change material layer 510 may be substantially the same as the process described with reference to FIG. 2C. Accordingly, the phase-change material layer 510 may include at least one chalcogenide compound having a composition in accordance with the above chemical formulae (1) to (8).

A first upper electrode film 515 and a second upper electrode film 520 are successively formed on the phase-change material layer 510. Thus, an upper electrode layer 525 is provided on the phase-change material layer 510. The first upper electrode film 515 may be formed using the stabilizing metal, and the second upper electrode film 520 may be formed using a metal compound.

In some example embodiments, when the upper electrode layer 525 is formed on the preliminary phase-change material layer, a stabilizing process may be additionally performed on the upper electrode layer 525 and the preliminary phase-change material layer. Hence, the preliminary phase-change material layer may be changed into the phase-change material layer 510. That is, the stabilizing metal included in the first upper electrode film 515 may be diffused into the preliminary phase-change material layer, thereby obtaining the phase-change material layer 510 that includes the chalcogenide compound doped with carbon and the stabilizing metal, or carbon, nitrogen and the stabilizing metal.

Referring to FIG. 15H, the upper electrode layer 525 and the phase-change material layer 510 are patterned by a photolithography process so that a phase-change material layer pattern 530 and the upper electrode 545 are formed on the lower electrode 505 and the second insulation layer 475. The upper electrode 545 includes a first upper electrode film pattern 535 and a second upper electrode film pattern 540. Each of the phase-change material layer pattern 530 and the upper electrode 545 may have a width substantially larger than that of the lower electrode 505.

An upper insulating layer 550 covering the upper electrode 545 is formed on the second insulation layer 475. The upper insulating layer 550 may be formed by a CVD process, a PECVD process, an LPCVD process, an HDP-CVD process, etc. Further, the upper insulating layer 550 may be formed using an oxide such as PSG, BPSG, USG, SOG, TEOS, PE-TEOS, FOX, HDP-CVD oxide, etc. In some example embodiments, the upper insulating layer 550 may be formed using an oxide substantially the same as that of the lower insulating layer 445, the sacrificial layer 480 and/or the first insulation layer 470. In other example embodiments, the upper insulating layer 550, the lower insulating interlayer 445, the sacrificial layer 480 and/or the first insulation layer 470 may be formed using difference oxides, respectively.

The upper insulating layer 550 may be partially etched by a photolithography process to form an upper contact hole 555 exposing the second upper electrode film pattern 540 of the upper electrode 545.

Referring to FIG. 15I, an upper pad 560 and an upper wiring 565 are formed on the second upper electrode film pattern 540 and the upper insulating layer 550. The upper pad 560 is positioned on the exposed second upper electrode film pattern 540 to fill up the upper contact hole 555. The upper wiring 565 is formed on the upper pad 560 and the upper insulating layer 550. The upper pad 560 and the upper wiring 565 may be formed using doped polysilicon, a metal or a metal compound. Further, the upper pad 560 and the upper wiring 565 may be formed by a sputtering process, a CVD process, an ALD process, an electron beam evaporation process, a PLD process, etc. In some example embodiments, the upper wiring 565 and the upper pad 560 may be integrally formed each other. In other example embodiments, the upper pad 560 may be formed on the upper electrode 545, and then the upper wiring 565 may be formed on the upper pad 560 and the upper insulating interlayer 550.

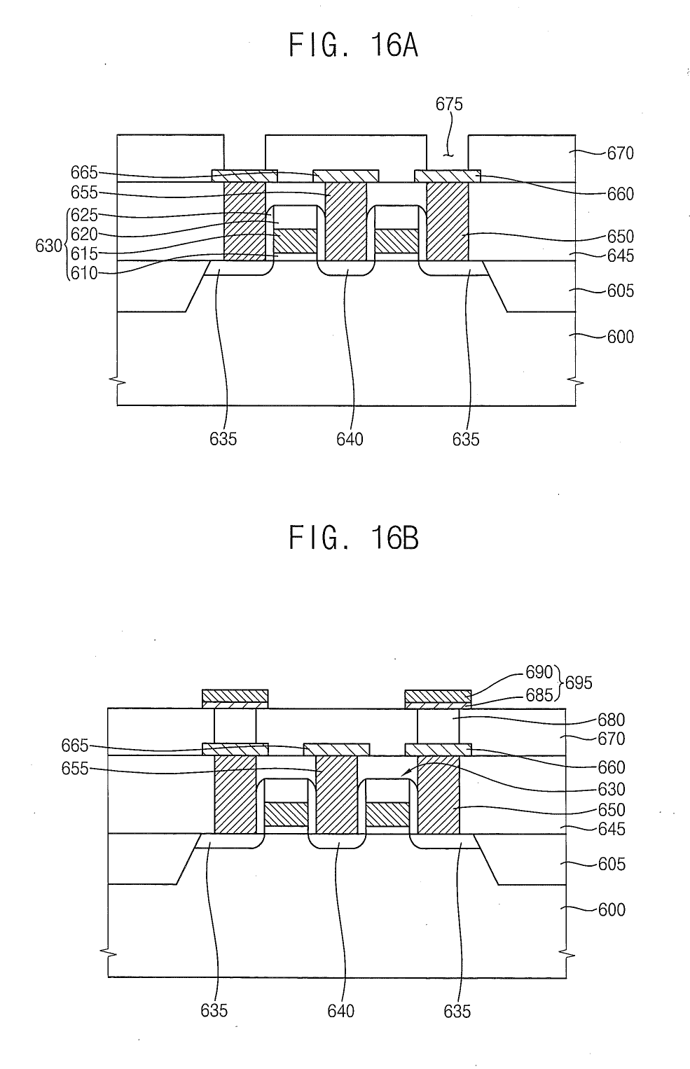

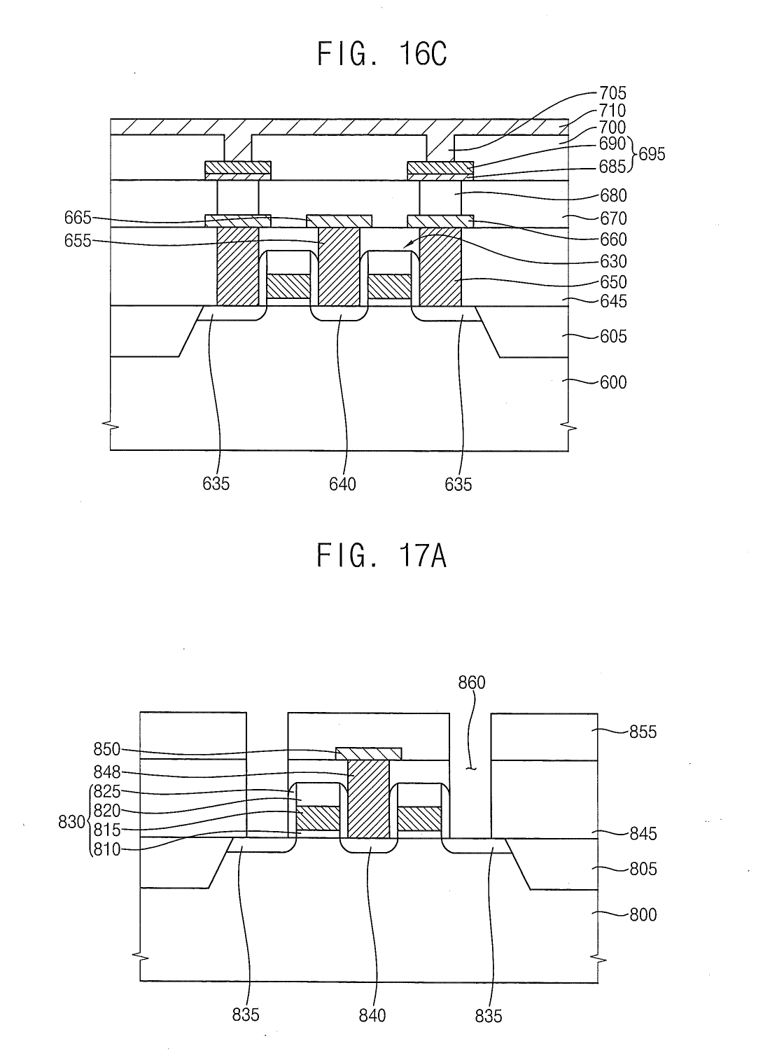

FIGS. 16A to 16C are cross-sectional views illustrating a method of manufacturing a phase-change memory device in accordance with example embodiments of the present invention. In FIGS. 16A to 16C, processes for forming an isolation layer 605, a gate structure 630, a first contact region 635, a second contact region 640, a lower insulating interlayer 645, a first pad 650, a second pad 655, a lower electrode 660 and a lower wiring 665 on a substrate 600 may be substantially the same as the processes described with reference to FIGS. 15A to 15C. For example, a process for forming the lower electrode 660 on the first pad 650 may correspond to the process for forming the third pad 460 on the first pad 450 as described with reference to FIG. 15C.

The gate structure 630 is positioned on an active region of the substrate 600. The gate structure 630 includes a gate insulation layer pattern 610, a gate conductive layer pattern 615, a gate mask 620 and a gate spacer 625.

Referring to FIG. 16A, an insulation layer 670 is formed on the lower insulating interlayer 645 to cover the lower electrode 660 and the lower wiring 665. The insulation layer 670 may be formed using an oxide by a CVD process, a PECVD process, an LPCVD process, an HDP-CVD process, etc. For example, the insulation layer 670 may be formed using PSG, BPSG, USG, SOG, TEOS, PE-TEOS, FOX, HDP-CVD oxide, etc.

The insulation layer 670 is partially etched by a photolithography process to form an opening 675 exposing the lower electrode 660 through the insulation layer 670. For example, the opening 675 may be formed an anisotropic etching process. Referring to FIG. 16B, a preliminary phase-change material layer (not illustrated) is formed on the lower electrode 660 to fill up the opening 675, and then a preliminary phase-change material layer pattern or a phase-change material layer pattern 680 is formed in the opening 675. The preliminary phase-change material layer pattern and the phase-change material layer pattern 680 may be formed by processes substantially the same as the above-described processes.

In some example embodiments, the preliminary phase-change material layer pattern may be changed into the phase-change material layer pattern 680 by a stabilizing process successively performed when the preliminary phase-change material layer pattern is formed in the opening 675. As described above, the preliminary phase-change material layer pattern may include a chalcogenide compound doped with carbon or carbon and nitrogen, and the phase-change material layer pattern 680 may include a chalcogenide compound doped with carbon and a stabilizing metal, or carbon nitrogen and the stabilizing metal.

A first upper electrode film and a second upper electrode film (not illustrated) are sequentially formed on the phase-change material layer pattern 680 or the preliminary phase-change material layer pattern. The second and the first upper electrode films are patterned to form an upper electrode 695 is formed on the phase-change material layer pattern 680 or the preliminary phase-change material layer pattern. The upper electrode 695 includes a first upper electrode film pattern 685 and a second upper electrode film pattern 690. The first upper electrode film pattern 685 is positioned on the phase-change material layer pattern 680 or the preliminary phase-change material layer pattern. The second upper electrode film pattern 690 locates on the first upper electrode film pattern 685. The first and the second upper electrode film patterns 685 and 690 may include the stabilizing metal and a metal compound, respectively.

Each of the lower electrode 660 and the upper electrode 695 may have a width substantially larger than a width of the phase-change material layer pattern 680 or the preliminary phase-change material layer pattern.

In some example embodiments, the stabilizing process may be executed on the upper electrode 695 and the preliminary phase-change material layer pattern to thereby form the phase-change material layer pattern 680 on the lower electrode 660.

Referring to FIG. 16C, an upper insulating interlayer 700 covering the upper electrode 695 is formed on the insulation layer 670. The upper insulating interlayer 700 may be formed using an oxide by a CVD process, a PECVD process, an LPCVD process, an HDP-CVD process, etc.

The upper insulating interlayer 700 is partially etched by a photolithography process to form an upper contact hole (not.illustrated) through the upper insulating interlayer 700. The upper contact hole exposes the upper electrode 695.

An upper pad 705 filling the upper contact hole is formed on the upper electrode 695, and then an upper wiring 710 is formed on the upper pad 705 and the upper insulating interlayer 700. The upper pad 700 and the upper wiring 710 may be integrally formed each other.

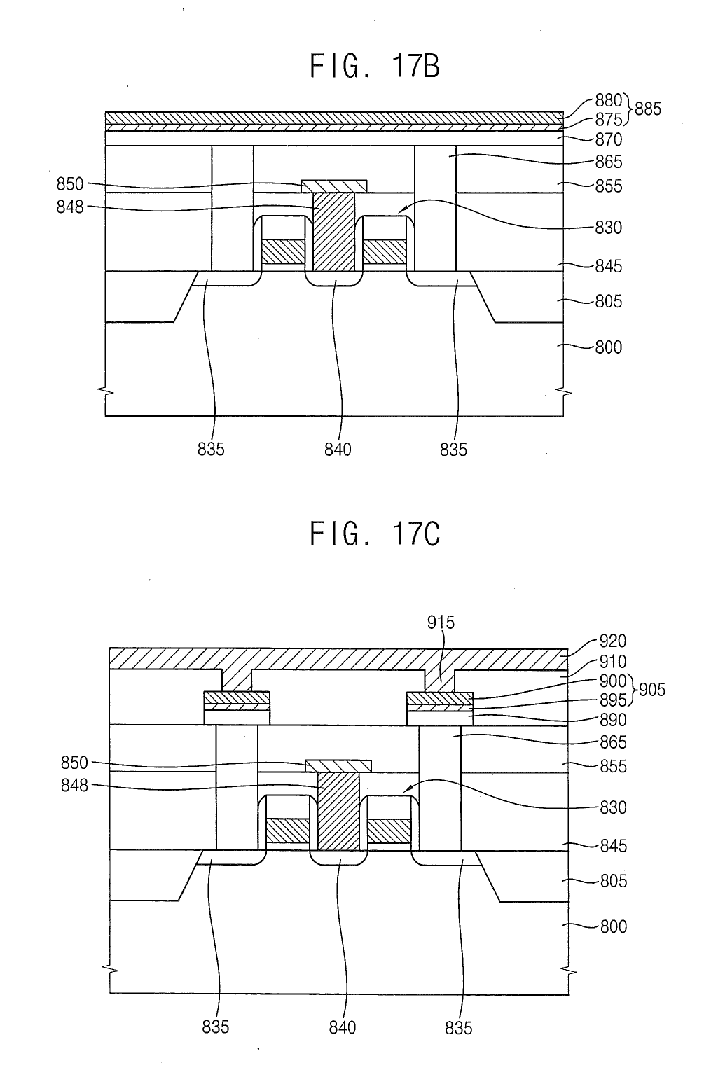

FIGS. 17A to 17C are cross-sectional views illustrating a method of manufacturing a phase-change memory device in accordance with example embodiments of the present invention. In FIGS. 17A to 17C, processes for forming an isolation layer 805, a gate structure 830, a first contact region 835, a second contact region 840 and a lower insulating interlayer 845 on a substrate 800 may be substantially the same as the processes described with reference to FIGS. 15A and 15B. The gate structure 830 is formed on an active region of the substrate 800. The gate structure 830 includes a gate insulation layer pattern 810, a gate conductive layer pattern 815, a gate mask 820 and a gate spacer 825.

Referring to FIG. 17A, the lower insulating interlayer 845 is partially etched to form a lower contact hole (not illustrated) through the lower insulating interlayer 845. The lower contact hole exposes the second contact region 840. Here, the first contact region 835 is not exposed after a formation of the lower contact hole.

A first lower conductive layer (not illustrated) is formed on the second contact region 840 and the lower insulating interlayer 845 to fill up the lower contact hole. The first lower conductive layer may be formed using doped polysilicon, a metal, a metal compound, etc.

The first lower conductive layer is partially removed until the lower insulating interlayer 845 is exposed to thereby form a lower pad 848 in the lower contact hole. The lower pad 848 filling the lower contact hole makes contact with the second contact region 840. The lower pad 848 may electrically connect a lower wiring 850 to the second contact region 840.

After a second conductive layer (not illustrated) is formed on the lower pad 848 and the lower insulating interlayer 845, the second conductive layer is patterned to form the lower wiring 850 on the lower pad 848. The lower wiring 850 may include a bit line. In some example embodiments, the lower pad 848 and the lower wiring 850 may be integrally formed each other. For example, a lower conductive layer (not illustrated) may be formed on the second contact region 840 and the lower insulating interlayer 845 to fill up the lower contact hole, and then the lower conductive layer may be patterned to simultaneously form the lower pad 848 and the lower wiring 850.

An insulation layer 855 is formed on the lower insulating interlayer 845 to cover the lower wiring 850. The insulation layer 855 may be formed by a process substantially the same as the process described with reference to FIG. 16A.

The insulation layer 855 and the lower insulating interlayer 845 are partially etched so that an opening 860 is formed through the insulation layer 855 and the lower insulating interlayer 845. The opening 860 exposes the first contact region 835.

Referring to FIG. 17B, a diode 865 is formed on the first contact region 835 to fill up the opening 860. The diode 865 may include polysilicon formed by an SEG process. Here, impurities, may be doped into polysilicon. The diode 865 may be formed using the first contact region 835 as a seed. In some example embodiments, the diode 865 may have a thickness substantially the same as an entire thickness of the lower insulating interlayer 845 and the insulation layer 855. In other example embodiments, the diode 865 may have a thickness substantially larger or smaller than a total thickness of the lower insulating interlayer 845 and the insulation layer 855.

A preliminary phase-change material layer (not illustrated) is formed on the diode 865 and the insulation layer 855. The preliminary phase-change material layer may be formed using a chalcogenide compound by a sputtering process or a CVD process. As described above, the preliminary phase-change material layer is changed into a phase-change material layer 870. Processes for forming the preliminary phase-change material layer and the phase-change material layer 870 may be substantially the same as those described with reference to FIG. 2C.

An upper electrode layer 885 including a first upper electrode film 875 and a second upper electrode film 880 is formed on the phase-change material layer 870 or the preliminary phase-change material layer. In some example embodiments, a stabilizing process may be executed on the preliminary phase-change material layer when the upper electrode layer 885 is formed on the preliminary phase-change material layer.

Referring to FIG. 17C, after photoresist pattern (not illustrated) is formed on the second upper electrode film 880, the upper electrode layer 885 and the phase-change material layer 870 are patterned using the photoresist pattern as an etching mask. Accordingly, a phase-change material layer pattern 890 and an electrode 905 are formed on the diode 865 and the insulation layer 855. The upper electrode 905 includes a first upper electrode film pattern 895 and a second upper electrode film pattern 900.

An upper insulating interlayer 910 is formed on the insulation layer 855 to cover the electrode 905, and then the upper insulating interlayer 910 is partially etched to form an upper contact hole (not illustrated) exposing the upper electrode 905. The upper insulating interlayer 910 may be formed using an oxide by a CVD process, a PECVD process, an LPCVD process, an HDP-CVD process, etc.

An upper pad 915 is formed on the upper electrode 905, and an upper wiring 920 is formed on the upper insulating interlayer 910 and the upper pad 915. The upper pad 915 and the upper wiring 920 may be formed using doped polysilicon, a metal or a metal compound. Further, the upper pad 915 and the upper wiring 920 may be formed by a sputtering process, a CVD process, an LPCVD process, an ALD process, an electron beam evaporation process, a PLD process, etc. The upper wiring 920 may be electrically connected to the upper electrode 905 through the upper pad 915.

According to example embodiments of the present invention, a phase-change material layer may be obtained by doping a stabilizing metal into a chalcogenide compound doped with carbon, or carbon and nitrogen, so that the phase-change material layer may have improved electrical characteristics, an enhanced stability of a phase transition, improved thermal characteristics, etc. When a phase-change memory unit or a phase-change memory device includes the phase-change material layer of a chalcogenide compound doped with carbon and the stabilizing metal, or carbon, nitrogen and the stabilizing metal, the phase-change memory unit or the phase-change memory device may have a considerably reduced set resistance, enhanced durability, improved reliability, etc. Further, the phase-change memory unit or the phase-change memory device may have enlarged sensing margin while efficiently reducing driving current thereof.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of this invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A phase-change memory unit comprising:
a lower electrode;
a phase-change material layer on the lower electrode, the phase-change material layer including a chalcogenide compound, carbon and a stabilizing metal, and the stabilizing metal including titanium; and
an upper electrode on the phase-change material layer.

2. The phase-change memory unit of claim 1, wherein at least one of the lower and upper electrodes includes titanium.

3. The phase-change memory unit of claim 1, wherein the phase-change material layer further includes nitrogen.

4. A phase-change memory device comprising:
a switching device on a substrate;
a lower electrode electrically connected to the switching device;
a phase-change material layer on the lower electrode, the phase-change material layer including a chalcogenide compound, carbon and a stabilizing metal, and the stabilizing metal including titanium; and
an upper electrode on the phase-change material layer.

5. The phase-change memory device of claim 4, wherein the switching device includes a diode.

6. The phase-change memory device of claim 4, wherein at least one of the lower and upper electrodes includes titanium.

7. The phase-change memory device of claim 4, wherein the phase-change material layer further includes nitrogen.
